(19) United States
(12) Patent Application Publication
(10) Pub. No.: US 2020/0212059 A1
(43) Pub. Date: Jul. 2, 2020

(54) SEMICONDUCTOR MEMORY DEVICE

(71) Applicant: Toshiba Memory Corporation, Minato-ku (JP)

(72) Inventor: Takuya NISHIKAWA, Yokkaichi (JP)

(73) Assignee: Toshiba Memory Corporation, Minato-ku (JP)

(21) Appl. No.: 16/522,310

(22) Filed: Jul. 25, 2019

(30) Foreign Application Priority Data
Dec. 26, 2018 (JP) 2018-243439

(51) Int. Cl. H01L 27/11582; G11C 5/06; H01L 27/1157; H01L 27/11524; H01L 27/11556

(52) U.S. Cl. CPC H01L 27/11582; G11C 5/063; H01L 27/11556; H01L 27/11524; H01L 27/1157

(57) ABSTRACT

A semiconductor memory device according to an embodiment includes first and second conductive layers, and a pillar. The pillar is penetrating the first conductive layers and the second semiconductor layers. The pillar includes first and second semiconductor layers, a third conductive layer, and a gate insulating film. The first semiconductor layer is facing the first conductive layers. The second semiconductor layer is facing the second conductive layers. The third conductive layer is provided between the second semiconductor layer and the second conductive layers. The gate insulating film is provided between the second semiconductor layer and the third conductive layer. The third conductive layer is electrically coupled to the second conductive layers.

### CROSS-REFERENCE TO RELATED APPLICATIONS

This application is based upon and claims the benefit of priority from Japanese Patent Application No. 2018-243439, filed Dec. 26, 2018, the entire contents of which are incorporated herein by reference.

### FIELD

Embodiments described herein relate generally to a semiconductor memory device.

### BACKGROUND

A NAND-type flash memory that is capable of storing data in a nonvolatile manner is known.

### BRIEF DESCRIPTION OF THE DRAWINGS

FIG. 1 is a block diagram showing a configuration example of a semiconductor memory device according to a first embodiment.

FIG. 2 is a circuit diagram showing an example of a circuit configuration of a memory cell array included in the semiconductor memory device according to the first embodiment.

FIG. 3 is a plan view showing an example of a planar layout of the memory cell array included in the semiconductor memory device according to the first embodiment.

FIG. 4 is a cross-sectional view showing an example of a cross-section structure of the memory cell array taken along line IV-IV of FIG. 3.

FIG. 5 is a cross-sectional view showing an example of a cross-sectional structure of a memory pillar taken along line V-V of FIG. 4.

FIG. 6 is a cross-sectional view showing an example of a cross-sectional structure of a memory pillar taken along line VI-VI of FIG. 4.

FIG. 7 is a flowchart showing an example of a manufacturing method of the semiconductor memory device according to the first embodiment.

FIGS. 8, 9, 10, 11, 12, 13, 14, 15, 16, 17, 18, 19, 20, 21, 22, 23, 24, and 25 are cross-sectional views of the memory cell array showing an example of manufacturing steps of the semiconductor memory device according to the first embodiment.

FIG. 26 is a cross-sectional view showing an example of a cross-sectional structure of a memory cell array included in a semiconductor memory device according to a second embodiment.

FIG. 27 is a cross-sectional view showing an example of a cross-sectional structure of a memory pillar taken along line XXVII-XXVII of FIG. 26.

FIG. 28 is a flowchart showing an example of a manufacturing method of the semiconductor memory device according to the second embodiment.

FIGS. 29, 30, 31, 32, 33, 34, 35, and 36 are cross-sectional views of the memory cell array showing an example of manufacturing steps of the semiconductor memory device according to the second embodiment.

FIG. 37 is a cross-sectional view showing an example of a cross-sectional structure of a memory cell array included in a semiconductor memory device according to a modified example of the second embodiment.

FIG. 38 is a cross-sectional view showing an example of a cross-sectional structure of the memory cell array included in the semiconductor memory device according to the first embodiment.

FIG. 39 is a cross-sectional view showing an example of a cross-sectional structure of a memory cell array included in a semiconductor memory device according to a modified example of the first embodiment.

### DETAILED DESCRIPTION

In general, according to one embodiment, a semiconductor memory device includes a plurality of first conductive layers, a plurality of second conductive layers, and a pillar. The first conductive layers are provided above a substrate. The first conductive layers are stacked apart from each other in a first direction. The second conductive layers are provided above the first conductive layers. The second conductive layers are stacked apart from each other in the first direction. The pillar is penetrating the first conductive layers and the second conductive layers. The pillar includes a first semiconductor layer, a second semiconductor layer, a third conductive layer, and a gate insulating film. The first semiconductor layer is extending in the first direction and facing the first conductive layers. The second semiconductor layer is extending in the first direction and facing the second conductive layers. The third conductive layer is extending in the first direction and provided between the second semiconductor layer and the second conductive layers. The gate insulating film is provided between the second semiconductor layer and the third conductive layer. An intersecting portion of the pillar and one of the first conductive layers functions as a memory cell transistor. An intersecting portion of the pillar and one of the second conductive layers functions as a select transistor. The third conductive layer is electrically coupled to the second conductive layers.

Hereinafter, embodiments will be explained with reference to the accompanying drawings. Each embodiment exemplifies a device and a method for embodying the technical idea of the invention. It should be noted that the drawings are schematic or conceptual, and that the dimensions and scales of the drawings are not necessarily the same as those of the actual products. The technical idea of the present invention is not specified by the shape, structure, arrangement, etc. of structural elements.

In the explanation below, structural elements having the same functions and configurations will be denoted by the same reference symbols. The numbers after the letters constituting the reference symbols are used to distinguish elements which are denoted by the reference symbols including the same letters and which have similar configurations. If there is no need of mutually distinguishing the elements which are denoted by the reference symbols that include the same letters, the same elements are denoted by the reference symbols that include only the letters.

### [1] First Embodiment

Hereinafter, a semiconductor memory device 1 according to a first embodiment will be explained.

[1-1] Configuration of Semiconductor Memory Device 1

[1-1-1] Overall Configuration of Semiconductor Memory Device 1

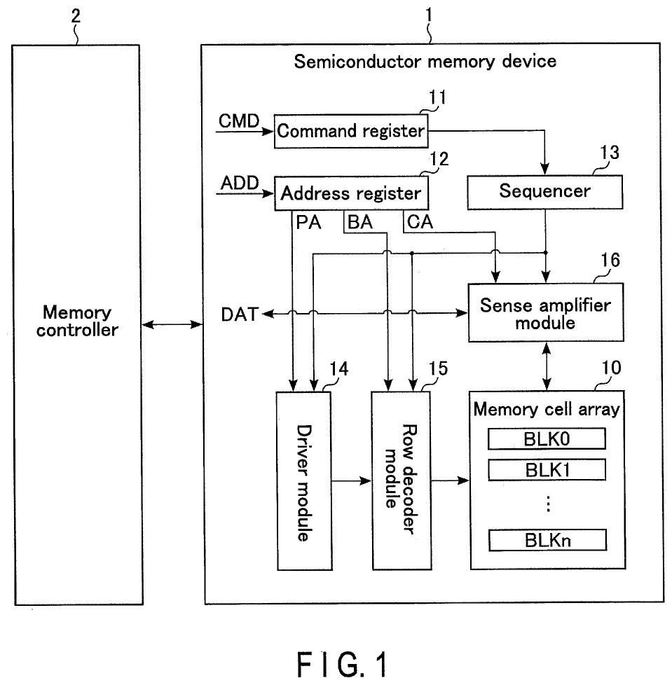

FIG. 1 shows a configuration example of the semiconductor memory device 1 according to the first embodiment. The semiconductor memory device 1 is a NAND-type flash memory that is capable of storing data in a non-volatile manner, and is controlled by an external memory controller 2. Communication between the semiconductor memory device 1 and the memory controller 2 supports, for example, a NAND interface standard.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or greater). A block BLK is a group of a plurality of memory cells capable of storing data in a non-volatile manner, and is used as, for example, a data erasure unit. In the memory cell array 10, a plurality of bit lines and a plurality of word lines are provided. Each memory cell is associated with, for example, one bit line and one word line. A detailed configuration of the memory cell array 10 will be described later.

The command register 11 retains a command CMD that is received by the semiconductor memory device 1 from the memory controller 2. The command CMD includes, for example, commands to cause the sequencer 13 to execute a read operation, a write operation, and an erase operation.

The address register 12 retains address information ADD received by the semiconductor memory device 1 from the memory controller 2. The address information ADD includes, for example, a block address BA, a page address PA, and a column address CA. For example, the block address BA, the page address PA, and the column address CA are used to select a block BLK, a word line, and a bit line, respectively.

The sequencer 13 controls the entire operation of the semiconductor memory device 1. For example, the sequencer 13 performs a read operation, a write operation, and an erase operation by controlling the driver module 14, the row decoder module 15, and the sense amplifier module 16, etc. based on a command CMD retained in the command register 11.

The driver module 14 generates a voltage to be used in a read operation, a write operation, and an erase operation, etc. The driver module 14 applies the generated voltage to a signal line corresponding to the selected word line based on, for example, a page address PA retained in the address register 12.

The row decoder module 15 selects one block BLK in a corresponding memory cell array 10 based on the block address BA retained in the address register 12. The row decoder module 15 transfers, for example, the voltage applied to the signal line corresponding to the selected word line to the selected word line in the selected block BLK.

The sense amplifier module 16, in a write operation, applies a desired voltage to each bit line in accordance with write data DAT received from the memory controller 2. The sense amplifier module 16, in a read operation, determines data stored in a memory cell based on the voltage of the bit line, and transfers the determination result as read data DAT to the memory controller 2.

The semiconductor memory device 1 and the memory controller 2 as described above may be combined to constitute one semiconductor device. Such a semiconductor device may be, for example, a memory card, such as an SD™ card, and a solid state drive (SSD).

[1-1-2] Circuit Configuration of Memory Cell Array 10

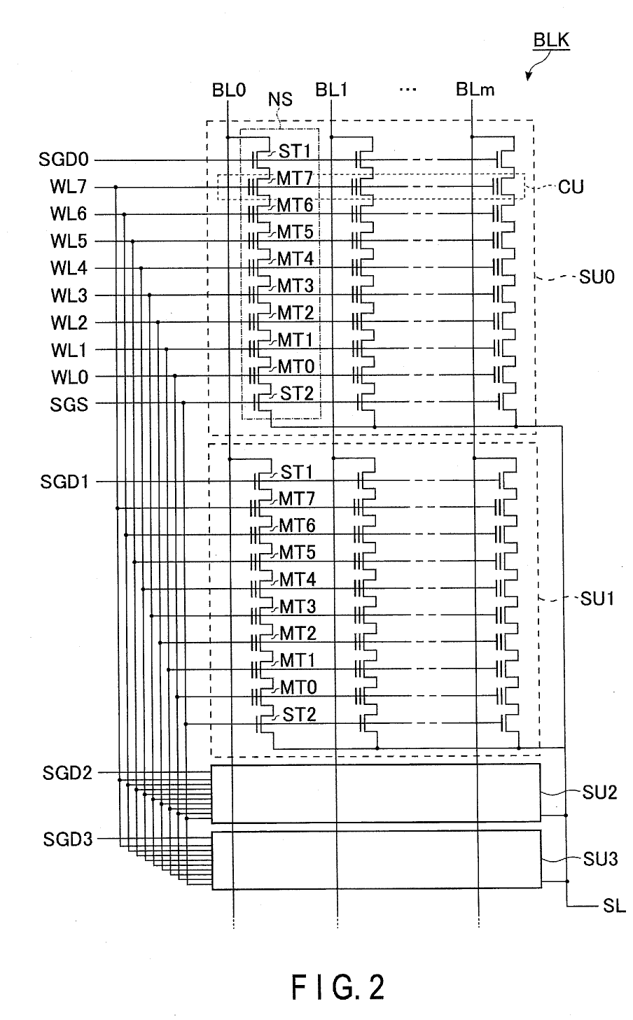

FIG. 2 shows an example of the circuit configuration of the memory cell array 10 in the semiconductor memory device 1 according to the first embodiment, by extracting one block BLK out of the plurality of blocks BLK included in the memory cell array 10. As shown in FIG. 2, the block BLK includes, for example, four string units SU0 to SU3.

Each string unit SU includes a plurality of NAND strings NS associated respectively with bit lines BL0 to BLm (where m is an integer equal to or greater than 1). Each NAND string NS includes, for example, memory cell transistors MT0 to MT7 and select transistors ST1 and ST2. Each memory cell transistor MT includes a control gate and a charge storage layer, and retains data in a non-volatile manner. Each of the select transistors ST1 and ST2 is used to select the string unit SU in various operations.

In each NAND string NS, the memory cell transistors MT0 to MT7 are coupled in series. A drain of the select transistor ST1 is coupled to an associated bit line BL, and a source of the select transistor ST1 is coupled to one end of the memory cell transistors MT0 to MT7 that are coupled in series. A drain of the select transistor ST2 is coupled to the other end of the memory cell transistors MT0 to MT7 that are coupled in series. A source of the select transistor ST2 is coupled to the source line SL.

In the same block BLK, the control gates of the memory cell transistors MT0 to MT7 are respectively coupled in common to word lines WL0 to WL7. In the string units SU0 to SU3, the gates of the select transistors ST1 are coupled in common to select gate lines SGD0 to SGD3, respectively. The gates of the select transistors ST2 are coupled in common to a select gate line SGS.

In the circuit configuration of the memory cell array 10 explained above, a bit line BL is shared by NAND strings NS to which the same column address is allocated in each string unit SU. The source line SL is, for example, shared among a plurality of blocks BLK.

A group of the plurality of memory cell transistors MT coupled to a common word line WL in one string unit SU is called, for example, a cell unit CU. For example, a storage capacity of the cell unit CU including memory cell transistors MT each storing 1-bit data is defined as “one-page data.” The storage capacity of the cell unit CU may be two-page data or more in accordance with the number of bits of data stored in the memory cell transistors MT.

The circuit configuration of the memory cell array 10 included in the semiconductor memory device 1 according to the first embodiment is not limited to the configuration described above. For example, each of the numbers of the memory cell transistors MT and the select transistors ST1 and ST2 that are included in each NAND string NS may be determined as appropriate. The number of string units SU included in each block BLK may be determined as appropriate.

[1-1-3] Structure of Memory Cell Array 10

An example of a structure of the memory cell array 10 according to the first embodiment will be explained below.

In the drawings referred to in the following, an X direction corresponds to the extending direction of bit lines BL, a Y direction corresponds to the extending direction of word lines WL, and a Z direction corresponds to a direction perpendicular to the surface of a semiconductor substrate 20, in which the semiconductor memory device 1 is formed. In the plan view, hatching is applied as appropriate for better viewability. The hatching applied to the plan view is not necessarily related to the materials or characteristics of the structural element to which the hatching is applied. For viewability, in the cross-sectional view, structural elements such as insulating layers (interlayer insulating films), wirings, and contacts, are suitably omitted.

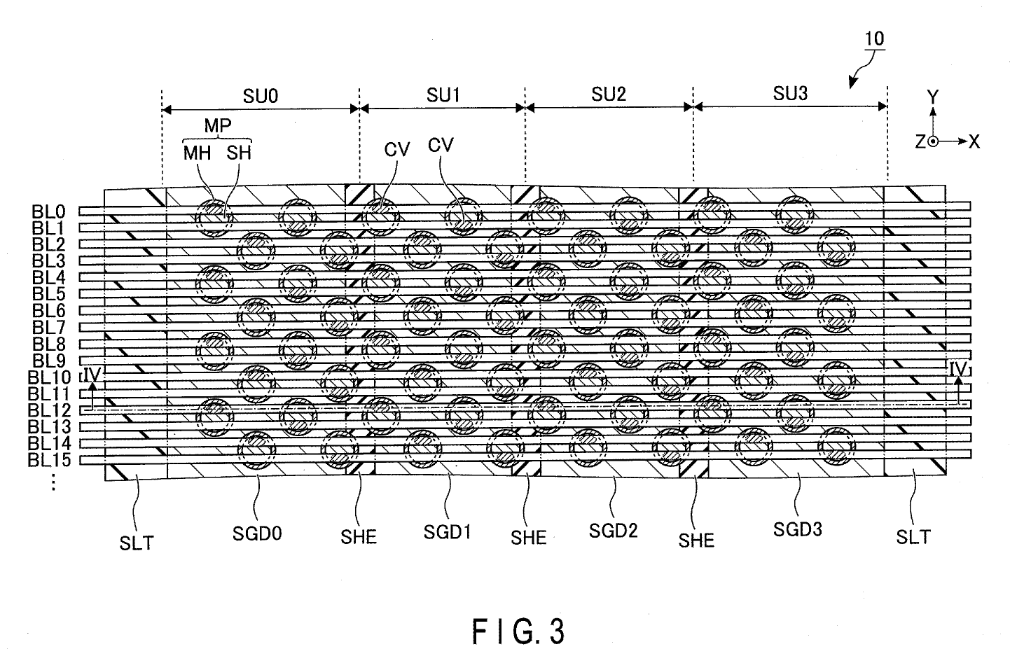

FIG. 3 is an example of a planar layout of the memory cell array 10 included in the semiconductor memory device 1 according to the first embodiment, and extracts a region including structures corresponding to the string units SU0 to SU3. As shown in FIG. 3, the memory cell array 10 includes, for example, slits SLT and SHE, memory pillars MP, contacts CV, and bit lines BL.

A plurality of slits SLT extend in the Y direction, and are arranged in the X direction, respectively. A plurality of slits SHE extend respectively in the Y direction, and are arranged in the X direction between the neighboring slits SLT. The slit SLT is, for example, wider than the slit SHE. Each of the slits SLT and SHE includes an insulator. The slit SLT divides, for example, each of the wiring layers corresponding to the word lines WL, the wiring layers corresponding to the select gate line SGD, and the wiring layers corresponding to the select gate line SGS. The slit SHE divides the wiring layers corresponding to the select gate line SGD.

The region separated by the slits SLT and SHE corresponds to one string unit SU. Specifically, for example, the string units SU0 to SU3 are provided between the slits SLT neighboring in the X direction. Four regions separated by the slits SHE between the slits SLT correspond respectively to the string units SU0 to SU3. That is, the semiconductor memory device 1 according to the first embodiment includes string units SU that are interposed between the slits SHE. In the memory cell array 10, for example, a similar layout is repeatedly arranged in the X direction.

For example, a plurality of memory pillars MP are arranged in a zigzag manner in 16 rows in the region between the neighboring slits SLT. Each of the memory pillars MP has a portion that is formed in a memory hole MH, and a portion that is formed in an SGD hole SH. The SGD hole SH is provided in a layer above the memory hole MH, and has a smaller diameter than the memory hole MH.

A set of corresponding memory hole MH and SGD hole SH includes an overlapped portion in a plan view. In the plan view, the center of the corresponding memory hole MH and the center of the SGD hole SH may or may not be overlapped. The memory pillar MP arranged in the vicinity of the slit SHE has a portion that overlaps the slit SHE. The semiconductor memory device 1 according to the first embodiment may be designed to have a layout in which the slit SHE and the memory pillar MP are allowed to come in contact.

A plurality of bit lines BL extend in the X direction, and are arranged in the Y direction, respectively. Each of the bit lines BL is arranged to overlap at least one SGD hole SH per string unit SU. For example, two bit lines BL overlap each of the SGD holes SH. The contact CV is provided between one bit line BL among a plurality of bit lines BL overlapping the SGD hole SH, and the SGD hole SH. The structure in the SGD hole SH is electrically coupled to a corresponding bit line BL via the contact CV.

The planar layout of the memory cell array 10 explained above is only an example, therefore, is not limited thereto. For example, the number of slits SHE that are arranged between the neighboring slits SLT may be determined as appropriate. The number of string units SU between the neighboring slits SLT varies based on the number of slits SHE. The number of memory pillars MP and the arrangement thereof may be determined as appropriate. The number of bit lines BL overlapping each of the memory pillars MP may be determined as appropriate.

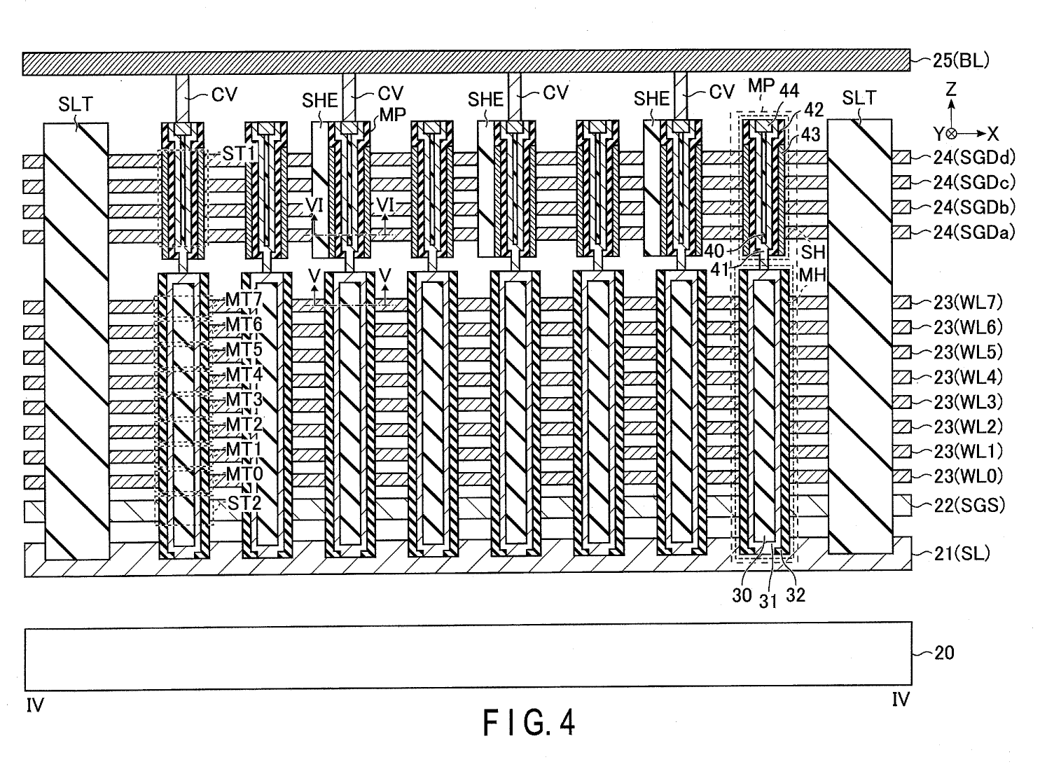

FIG. 4 is a cross-sectional view taken along line IV-IV of FIG. 3, and shows an example of a cross-sectional structure of the memory cell array 10 included in the semiconductor memory device 1 according to the first embodiment. As shown in FIG. 4, the memory cell array 10 further includes, for example, conductive layers 21 to 25. The conductive layers 21 to 25 are provided above the semiconductor substrate 20.

Specifically, the conductive layer 21 is provided above the semiconductor substrate 20 via an insulating layer. Although not shown, for example, in the insulating layer between the semiconductor substrate 20 and the conductive layer 21, a circuit such as the sense amplifier module 16 is provided. For example, the conductive layer 21 is formed in a plate-like shape extending along the XY plane, and is used as a source line SL. The conductive layer 21 includes, for example, silicon (Si).

A conductive layer 22 is provided above the conductive layer 21 via an insulating layer. For example, the conductive layer 22 is formed in a plate-like shape extending along the XY plane, and is used as a select gate line SGS. The conductive layer 22 includes, for example, silicon (Si).

The insulating layers and the conductive layers 23 are alternately stacked above the conductive layer 22. For example, the conductive layers 23 are formed in a plate-like shape extending along the XY plane. For example, the plurality of stacked conductive layers 23 are used respectively in sequence as word lines WL0 to WL7, from the semiconductor substrate 20 side. The conductive layers 23 include, for example, tungsten (W).

For example, four conductive layers 24 are stacked above the uppermost conductive layer 23 via an insulating layer. The interval between the uppermost conductive layer 23 and the lowermost conductive layer 24 in the Z direction is larger than the interval between the neighboring conductive layers 23 in the Z direction. In other words, the thickness of the insulating layer between the uppermost conductive layer 23 and the lowermost conductive layer 24 is thicker than the thickness of the insulating layer between the neighboring conductive layers 23.

An insulating layer is provided between the neighboring conductive layers 24. For example, the conductive layer 24 is formed in a plate-like shape extending along the XY plane, and is used as a select gate line SGD. In the following, the stacked four conductive layers 24 will be referred to respectively as select gate lines SGDa, SGDb, SGDc, and SGDd in sequence, from the semiconductor substrate 20 side. A set of overlapped select gate lines SGDa, SGDb, SGDc, and SGDd is used as the select gate line SGD. The conductive layer 24 includes tungsten (W), for example.

The conductive layer 25 is provided above the uppermost conductive layer 24 with an insulation layer being interposed therebetween. For example, the conductive layer 25 is formed in a linear shape extending along the X direction, and is used as the bit line BL. That is, a plurality of conductive layers 25 are arranged along the Y direction in a region not shown. A conductive layer 25 includes, for example, copper (Cu).

The memory pillar MP extends along the Z direction, and penetrates the conductive layers 22 to 24. Specifically, a portion corresponding to the memory hole MH of the memory pillar MP penetrates the conductive layers 22 and 23, and the bottom part thereof contacts the conductive layer 21. A portion corresponding to the SGD hole SH of the memory pillar MP is provided above the portion corresponding to the memory hole MH, and penetrates the stacked conductive layers 24. A layer including a boundary between the memory hole MH and the SGD hole SH is included in a layer between the uppermost conductive layer 23 and the lowermost conductive layer 24.

Furthermore, the memory pillar MP includes, for example, a core member 30, a semiconductor layer 31, a stacked film 32, a core member 40, a semiconductor layer 41, an insulating layer 42, a conductive layer 43, and a semiconductor portion 44. The core member 30, the semiconductor layer 31, and the stacked film 32 are included in the portion corresponding to the memory hole MH. The core member 40, the semiconductor layer 41, the insulating layer 42, the conductive layer 43, and the semiconductor portion 44 are included in the portion corresponding to the SGD hole SH.

The core member 30 extends along the Z direction. An upper end of the core member 30 is included in, for example, a layer above the layer in which the uppermost conductive layer 23 is provided, and a lower end of the core member 30 is included in, for example, a layer in which the conductive layer 21 is provided. The core member 30 includes an insulator such as silicon oxide (SiO₂).

The semiconductor layer 31 covers the core member 30. The semiconductor layer 31 includes, for example, a portion that is cylindrically provided. For example, a bottom part of the semiconductor layer 31 contacts the conductive layer 21. The semiconductor layer 31 provided on a side surface and a bottom surface of the core member 30, and the semiconductor layer 31 provided on top of the core member 30 are formed by different processes.

Except for a portion at which the conductive layer 21 and the semiconductor layer 31 come in contact, the stacked film 32 covers the side surface and the bottom surface of the semiconductor layer 31 in the memory hole MH. The stacked film 32 includes, for example, a portion that is cylindrically provided. The detailed layer structure of the stacked film 32 will be described later.

The core member 40 extends along the Z direction. For example, an upper end of the core member 40 is included in a layer above the layer in which the uppermost conductive layer 24 is provided, and a lower end of the core member 40 is included in a layer between the uppermost conductive layer 23 and the lowermost conductive layer 24. The core member 40 includes an insulator such as silicon oxide.

The semiconductor layer 41 includes a first portion that covers a side surface and a bottom surface of the core member 40, and a second portion that extends in the Z direction from a bottom part of the core member 40. The first portion of the semiconductor layer 41 includes, for example, a portion that is cylindrically provided. For example, an upper end of the first portion of the semiconductor layer 41 is included in a layer above the layer in which the uppermost conductive layer 24 is provided, and a lower end of the first portion of the semiconductor layer 41 is included in a layer between the uppermost conductive layer 23 and the lowermost conductive layer 24. The second portion of the semiconductor layer 41 is in contact with an upper surface of the semiconductor layer 31 in the corresponding memory hole MH.

The insulating layer 42 covers a side surface and a bottom surface of the first portion of the semiconductor layer 41. The insulating layer 42 includes, for example, a portion that is cylindrically provided. For example, an upper end of the insulating layer 42 is included in a layer above the layer in which the uppermost conductive layer 24 is provided, and a lower end of the insulating layer 42 is included in a layer between the uppermost conductive layer 23 and the lowermost conductive layer 24. The insulating layer 42 includes an insulator such as silicon oxide.

The conductive layer 43 covers a part of a side surface of the insulating layer 42. The conductive layer 43 includes a portion that is cylindrically provided. For example, an upper end of the conductive layer 43 is included in a layer above the layer in which the uppermost conductive layer 24 is provided, and a lower end of the conductive layer 43 is included in a layer between the uppermost conductive layer 23 and the lowermost conductive layer 24. The conductive layer 43 is electrically coupled to the select gate lines SGDa, SGDb, SGDc, and SGDd through which it penetrates.

The semiconductor portion 44 contacts an inner wall of the semiconductor layer 41 through its side surface, and contacts the core member 40 and the semiconductor layer 41 through its bottom surface. The semiconductor portion 44 is included in a layer above the uppermost conductive layer 24. The semiconductor portion 44 is provided by, for example, the same material as the semiconductor layer 41.

In the structure in the SGD hole SH explained above, the semiconductor layer 41 and the insulating layer 42 have a portion provided along the upper end of the conductive layer 43. A part of the side surface of the insulating layer 42 and the side surface of the conductive layer 43 are in contact with the inner wall of the SGD hole SH. For example, the upper ends of the semiconductor layer 41, the insulating layer 42, and the semiconductor portion 44 are aligned.

A columnar contact CV is provided on the upper surfaces of the semiconductor layer 41 and the semiconductor portion 44 in the memory pillar MP. In the illustrated region, contacts CV corresponding to four memory pillars MP among the eight memory pillars MP are shown. To memory pillars MP to which the contacts CV are not coupled in the above region, contacts CV are coupled in a region that is not shown. An upper surface of the contact CV is in contact with one conductive layer 25, that is, one bit line BL. One contact CV is coupled to one bit line BL in each of the space that is partitioned by the slits SLT and SHE.

The slit SLT is formed into, for example, a plate-like shape extending along the YZ plane, and divides the conductive layers 22 to 24. An upper end of the slit SLT is included in a layer between the uppermost conductive layer 24 and the conductive layer 25. A lower end of the slit SLT is included in, for example, a layer where the conductive layer 21 is provided. The slit SLT includes an insulator such as silicon oxide.

The slit SHE is formed into, for example, a plate-like shape extending along the YZ plane, and divides the stacked conductive layer 24. An upper end of the slit SHE is included in a layer between the uppermost conductive layer 24 and the conductive layer 25. A lower end of the slit SHE is included, for example, in a layer between the layer in which the uppermost conductive layer 23 is provided and the layer in which the lowermost conductive layer 24 is provided. The slit SHE includes an insulator such as silicon oxide.

The upper end of the slit SLT and the upper end of the slit SHE are aligned. The upper end of the memory pillar MP and the upper ends of the slits SLT and SHE may or may not be aligned. The lower end of the conductive layer 43 and the lower end of the slit SHE may or may not be aligned.

FIG. 5 is a cross-sectional view taken along line V-V of FIG. 4, and shows an example of a cross-sectional structure of the memory pillar MP in the semiconductor memory device 1 according to the first embodiment. More specifically, FIG. 5 shows a cross-sectional structure of a portion corresponding to the memory hole MH of the memory pillar MP in a layer that is parallel to the surface of the semiconductor substrate 20 and that includes the conductive layer 23.

As shown in FIG. 5, in the layer including the conductive layer 23, for example, the core member 30 is provided at the center of the memory pillar MP. The semiconductor layer 31 surrounds the side surface of the core member 30. The stacked film 32 surrounds the side surface of the semiconductor layer 31. Specifically, the stacked film 32 includes, for example, a tunnel insulating film 33, an insulating film 34, and a block insulating film 35.

The tunnel insulating film 33 surrounds the side surface of the semiconductor layer 31. The insulating film 34 surrounds the side surface of the tunnel insulating film 33. The block insulating film 35 surrounds the side surface of the insulation film 34. The conductive layer 23 surrounds the side surface of the block insulating film 35. Each of the tunnel insulating film 33 and the block insulating film 35 includes, for example, silicon oxide. The insulating film 34 includes, for example, silicon nitride (SiN).

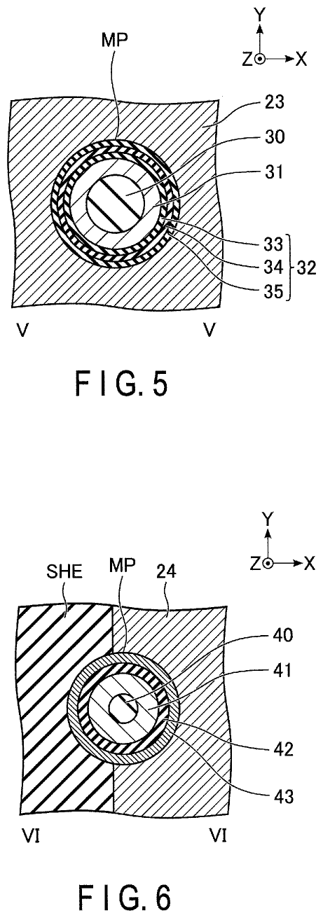

FIG. 6 is a cross-sectional view taken along line VI-VI of FIG. 4, and shows an example of a cross-sectional structure of the memory pillar MP in the semiconductor memory device 1 according to the first embodiment. More specifically, FIG. 6 shows a cross-sectional structure of a portion corresponding to the SGD hole SH of the memory pillar MP in a layer that is parallel to the surface of the semiconductor substrate 20 and that includes the conductive layer 24. Furthermore, in the region shown in FIG. 6, the memory pillar MP and the slit SHE are in contact.

As shown in FIG. 6, in the layer including the conductive layer 24, for example, the core member 40 is provided at the center of the SGD hole SH. The semiconductor layer 41 surrounds the side surface of the core member 40. The insulating layer 42 surrounds the side surface of the semiconductor layer 41. The conductive layer 43 surrounds the side surface of the insulating layer 42. The side surface of the conductive layer 43 contacts, for example, each of the conductive layer 24 and the slit SHE.

In the structure of the memory pillar MP explained above, a portion at which the memory pillar MP and the conductive layer 22 intersect functions as the select transistor ST2. A portion at which the memory pillar MP and the conductive layer 23 intersect functions as the memory cell transistor MT. A portion at which the memory pillar MP and the conductive layer 24 intersect functions as the select transistor ST1.

In other words, the semiconductor layer 31 is used as a channel of each of the memory cell transistor MT and the select transistor ST2. The insulating film 34 is used as a charge storage layer of the memory cell transistor MT. The semiconductor layer 41 is used as a channel of a select transistor ST1. The insulating layer 42 is used as a gate insulating film of the select transistor ST1. In this manner, each of the memory pillars MP functions as, for example, one NAND string NS.

The structure of the memory cell array 10 explained above is merely an example; therefore, the memory cell array 10 may have other structures. For example, the number of the conductive layers 23 is determined based on the number of the word lines WL. A plurality of conductive layers 22 provided in a plurality of layers may be allocated as the select gate lines SGS. If the select gate lines SGS are provided in a plurality of layers, a conductor different from the conductive layer 22 may be used. At least two layers are provided for the conductive layer 24 corresponding to the select gate line SGD. The memory pillar MP may be electrically coupled to the conductive layer 25 via two or more contacts, or via other wirings. The slit SLT may be configured to include multiple types of insulators. For example, before the slit SLT is filled with silicon oxide, silicon nitride may be formed as a side wall of the slit SLT.

[1-2] Manufacturing Method of Semiconductor Memory Device 1

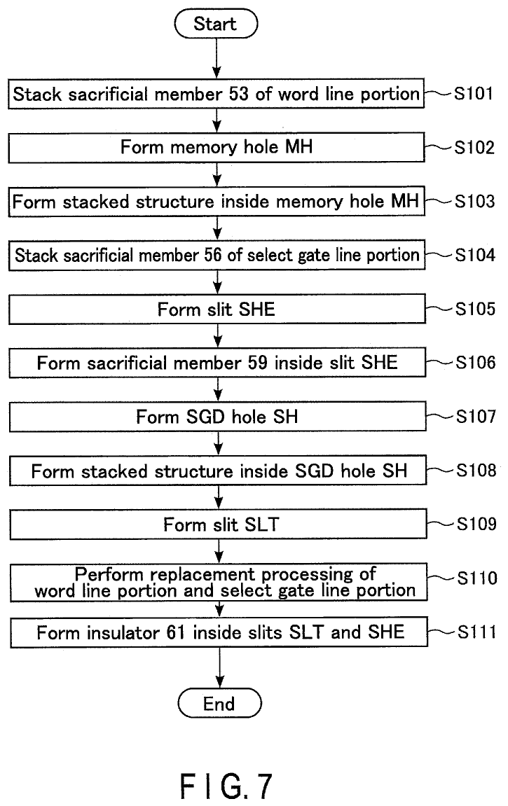

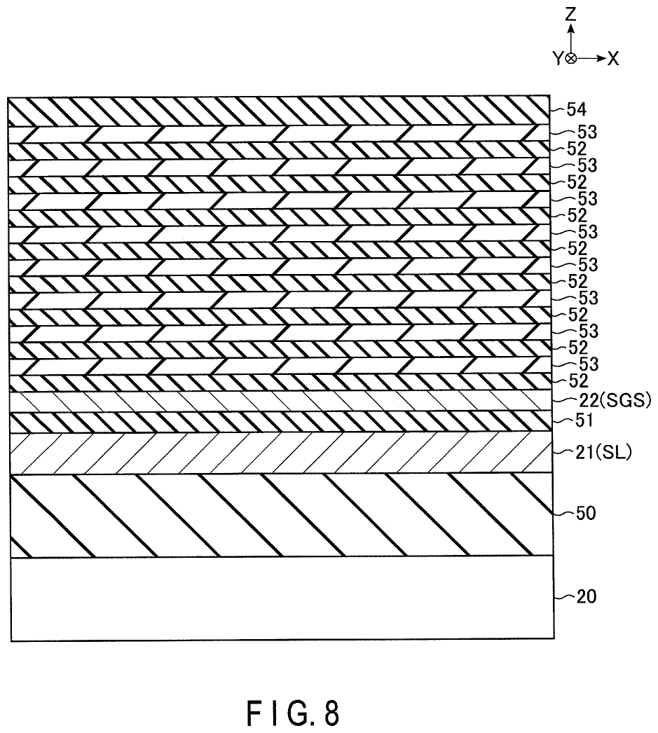

In the following, an example of a series of manufacturing processes from forming a stacked structure corresponding to the word line WL to forming the slits SLT in the semiconductor memory device 1 according to the first embodiment will be explained with reference to FIG. 7 as needed. FIG. 7 is a flowchart showing an example of a manufacturing method of the semiconductor memory device 1 according to the first embodiment. Each of FIG. 8 to FIG. 25 shows an example of a cross-sectional structure including a structure corresponding to the memory cell array 10 in the manufacturing process of the semiconductor memory device 1 according to the first embodiment. The cross-sectional view of the manufacturing process referred to below includes a cross-section that is parallel to the surface of the semiconductor substrate 20 and a cross-section perpendicular to the surface of the semiconductor substrate 20. Furthermore, the region denoted in the cross-sectional view of each of the manufacturing processes includes a region in which each of the plurality of memory pillars MP and the slits SLT and SHE are formed.

First of all, the processing of step S101 is performed, in which a sacrificial member 53 of the word line portion is stacked in the manner shown in FIG. 8. Specifically, first, an insulating layer 50, a conductive layer 21, an insulating layer 51, and a conductive layer 22 are stacked on the semiconductor substrate 20 in sequence. Although not shown, a circuit corresponding to the sense amplifier module 16, etc. is formed in the insulating layer 50. Subsequently, insulating layers 52 and sacrificial members 53 are alternately stacked on the conductive layer 22, and an insulating layer 54 is formed on an uppermost layer of the sacrificial member 53.

The conductive layer 21 is used as the source line SL, and the conductive layer 22 is used as the select gate line SGS. Each of the conductive layers 21 and 22 includes, for example, silicon (Si). Each of the insulating layers 51, 52, and 54 includes, for example, silicon oxide (SiO₂). For example, the number of layers in which the sacrificial members 53 are formed corresponds to the number of word lines WL that are stacked. The sacrificial member 53 includes, for example, silicon nitride (SiN).

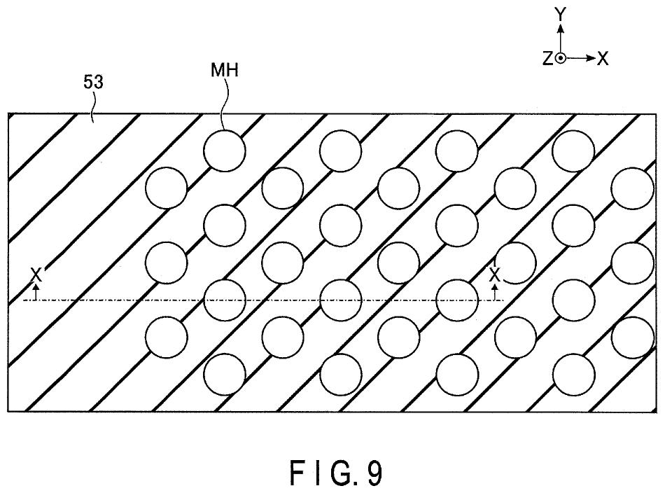

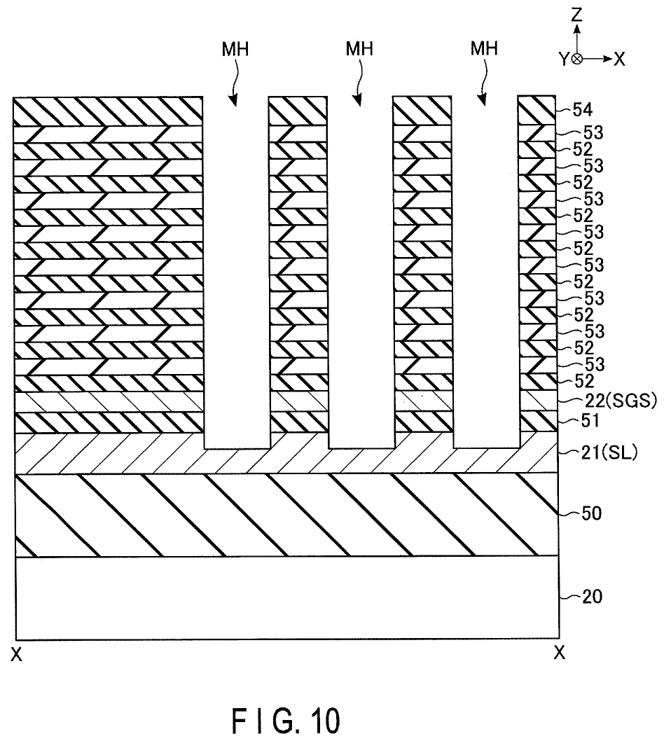

Next, the processing of step S102 is performed to form the memory holes MH in the manners shown in FIG. 9 and FIG. 10. Specifically, first, a mask in which regions corresponding to the memory holes MH are opened is formed by photolithography, etc. Then, the memory holes MH are formed by anisotropic etching using the formed mask. In a plan view, the plurality of memory holes MH are arranged in a zig-zag manner.

The memory hole MH formed in the present process penetrates each of the insulating layers 51, 52, and 54, the sacrificial member 53, and the conductive layer 22. The bottom part of the memory hole MH stops, for example, in the conductive layer 21. The anisotropic etching in the present process is, for example, Reactive Ion Etching (RIE).

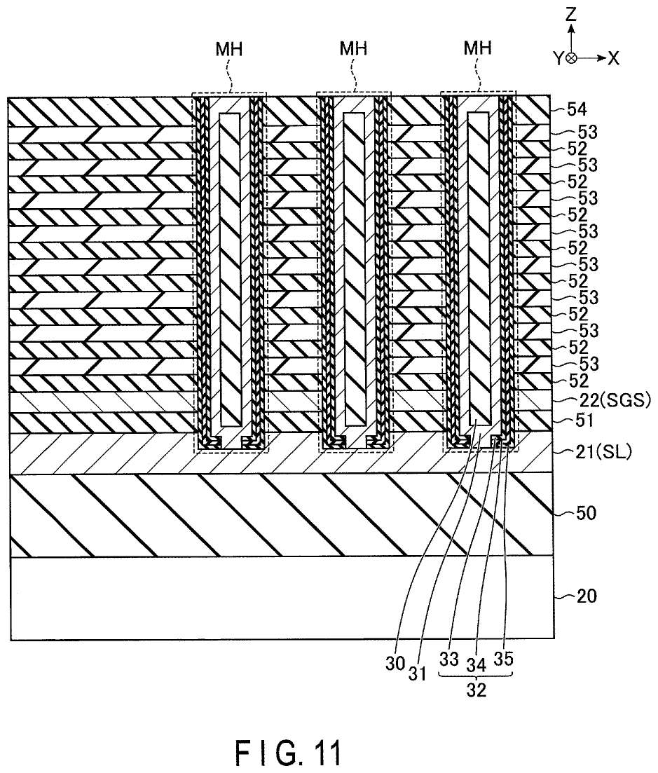

Next, the processing of step S103 is performed to form a stacked structure in the memory hole MH in the manner shown in FIG. 11. Specifically, the stacked film 32 is formed on the side surface and the bottom surface of the memory hole MH, and on the upper surface of the insulating layer 54. That is, the block insulating film 35, the insulating film 34, and the tunnel insulating film 33 are formed in sequence.

After the stacked film 32 on the bottom part of the memory hole MH is removed, the semiconductor layer 31 and the core member 30 are formed in sequence, and the memory hole MH is filled with the core member 30. Then, a part of the core member 30 formed on the upper part of the memory hole MH is removed, and a semiconductor material is filled in the space. Subsequently, the stacked film 32, the semiconductor layer 31, and the semiconductor material that remain in a layer above the insulating layer 54 are removed. In this manner, a structure corresponding to the memory pillar MP is formed in the memory hole MH.

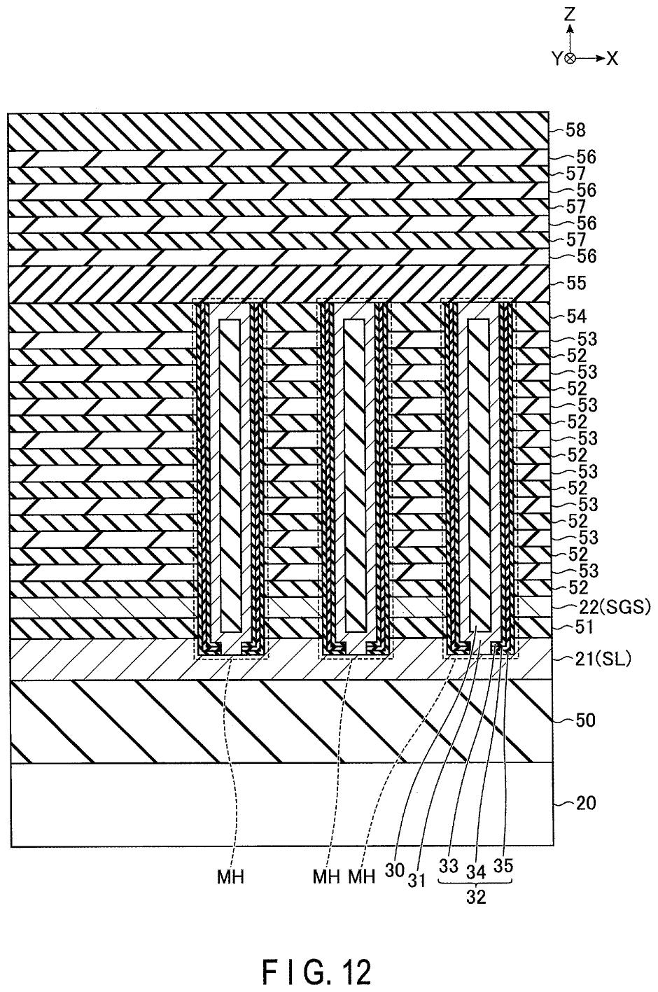

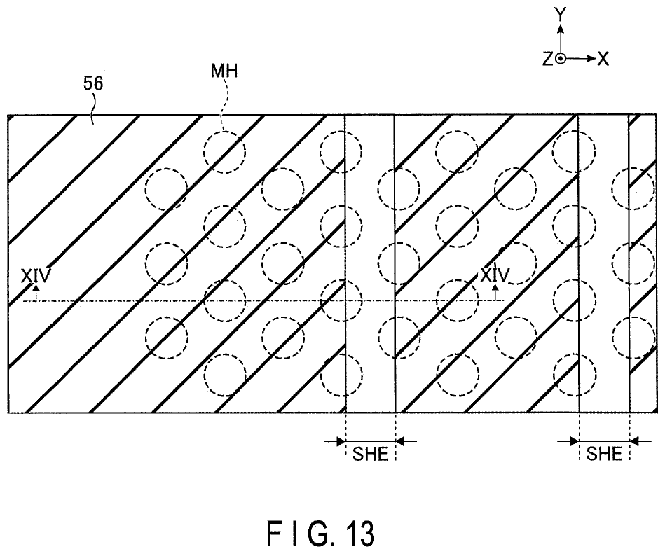

Next, the processing of step S104 is performed, in which a sacrificial member 56 of a select gate line portion is stacked in the manner shown in FIG. 12. Specifically, an insulating layer 55 is formed on the insulating layer 54, and the sacrificial member 56 and an insulating layer 57 are alternately stacked on the insulating layer 55. An insulating layer 58 is formed on the uppermost sacrificial member 56. Each of the insulating layers 55, 57, and 58 includes, for example, silicon oxide (SiO₂). The number of layers in which the sacrificial members 56 are formed corresponds to the number of select gate lines SGDa, SGDb, SGDc, and SGDd that are stacked. For example, the sacrificial member 56 is formed by the same material as the sacrificial member 53, and includes silicon nitride (SiN).

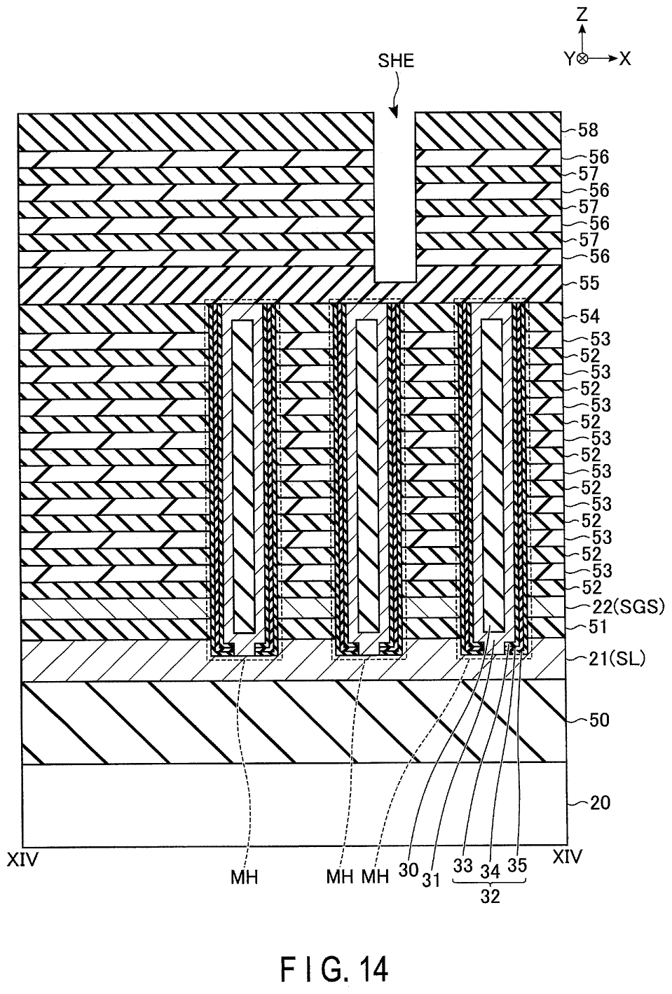

Next, the processing of step S105 is performed to form the slit SHE in the manners shown in FIG. 13 and FIG. 14. Specifically, first, a mask in which regions corresponding to the slits SHE are opened is formed by photolithography, etc. The slit SHE is formed by anisotropic etching using the formed mask. In a plan view, the slit SHE has a portion overlapping the memory holes MH that are arranged in a zig-zag manner.

The slit SHE formed in the present process divides each of the insulating layers 57 and 58, and the sacrificial member 56. The bottom part of the slit SHE stops, for example, in a layer in which the insulating layer 55 is provided. The slit SHE divides at least all of the sacrificial members 56 that are stacked. The anisotropic etching in the present process is, for example, RIE.

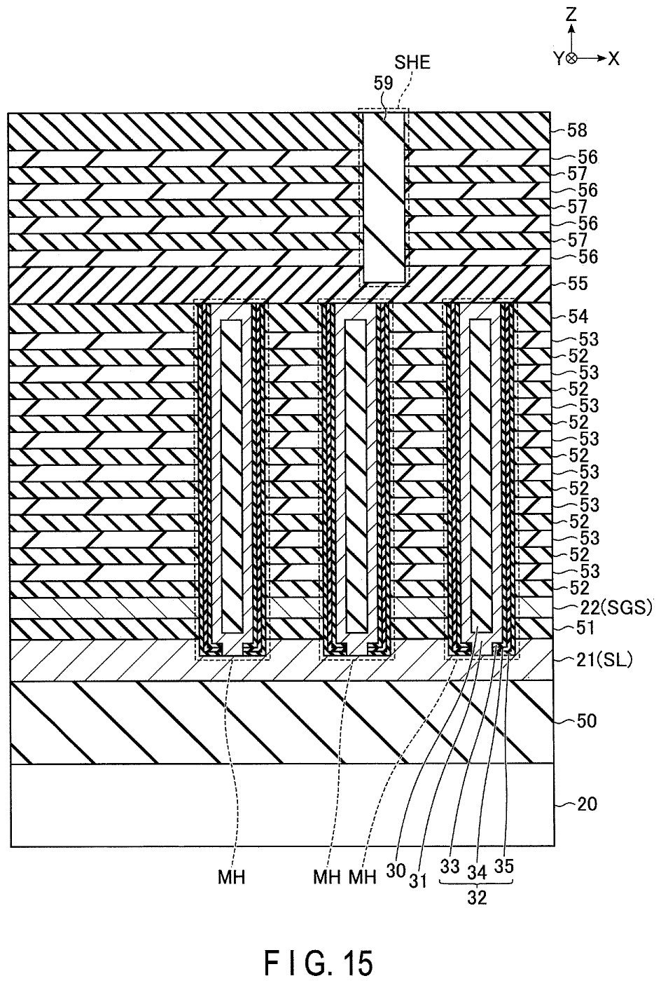

Next, the processing of step S106 is performed to form a sacrificial member 59 in the slit SHE in the manner shown in FIG. 15. Specifically, the sacrificial member 59 is formed so as to fill the slit SHE above the insulating layer 58. The sacrificial member 59 formed in a layer above the insulating layer 58 is removed by, for example, etchback processing. For example, the sacrificial member 59 is formed by the same material as the sacrificial member 56, and includes silicon nitride (SiN).

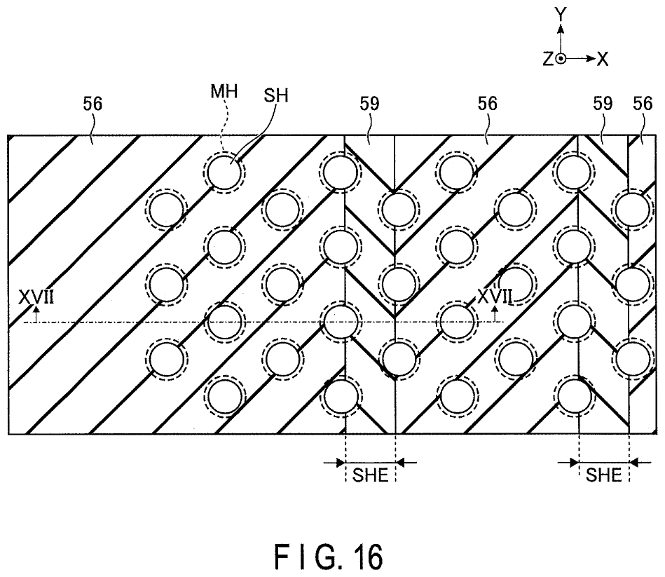

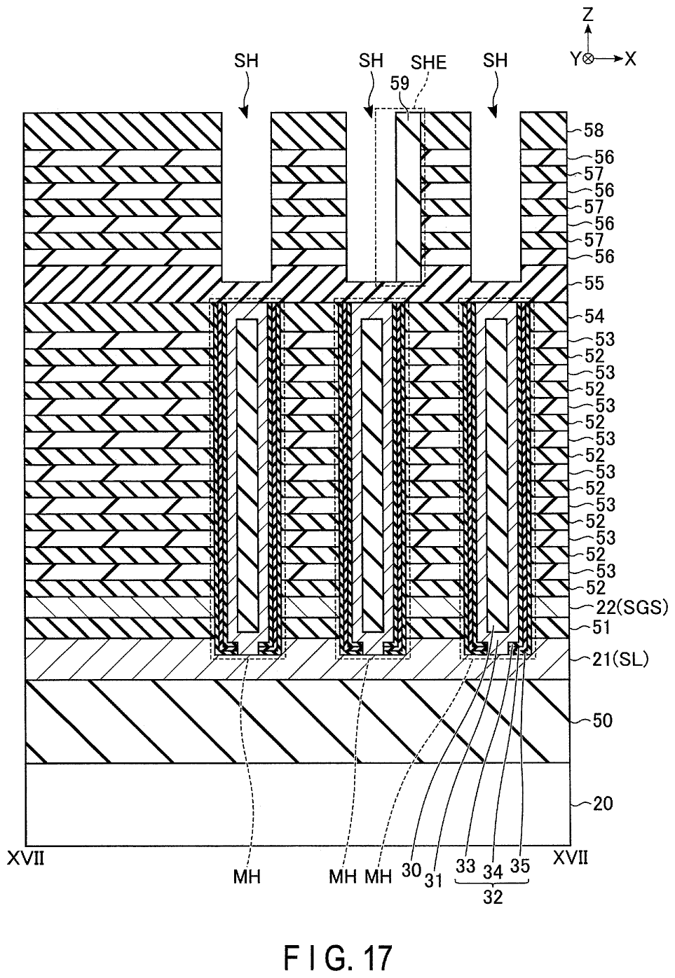

Next, the processing of step S107 is performed to form the SGD hole SH in the manners shown in FIG. 16 and FIG. 17. Specifically, first, a mask in which regions corresponding to the SGD holes SH are opened is formed by photolithography, etc. Then, the SGD holes SH are formed by anisotropic etching using the formed mask. In a plan view, a plurality of SGD holes SH overlap a plurality of memory holes MH, respectively. Furthermore, the plurality of SGD holes SH include SGD holes SH that overlap with the slit SHE.

The SGD hole SH formed in the present process penetrates each of the insulating layers 57 and 58, and the sacrificial member 56. The bottom part of the SGD hole SH stops, for example, in the insulating layer 55. The bottom part of the SGD hole SH may or may not be aligned with the bottom part of the slit SHE. The anisotropic etching in the present process is, for example, RIE.

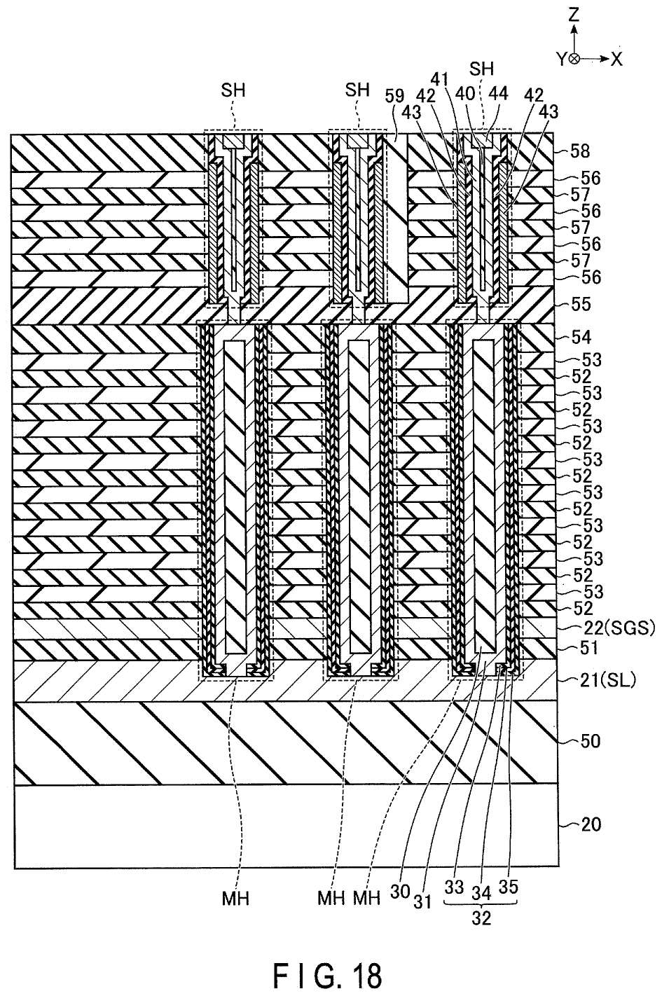

Next, the processing of step S108 is performed to form a stacked structure in the SGD hole SH in the manner shown in FIG. 18. Specifically, first, the conductive layer 43 is formed on the side surface and the bottom surface of the SGD hole SH. Subsequently, for example, the conductive layer 43 on the bottom part of the SGD hole SH is removed by etchback processing. The height adjustment of the conductive layer 43 may be performed by etching after forming a sacrificial member in a desired height in the SGD hole SH.

The insulating layer 42 is formed on the side surface and the bottom surface of the SGD hole SH. Subsequently, the insulating layer 42 on the bottom part of the SGD hole SH is removed by etchback processing, and, at the bottom part of each of the SGD holes SH, the insulating layer 55 directly beneath the SGD hole SH is further etched, thereby exposing the upper surface of the semiconductor layer 31 in the corresponding memory hole MH. The semiconductor layer 41 and the core member 40 are formed in sequence, and the SGD hole SH is filled by the core member 40. Subsequently, a part of the core member 40 formed on the upper part of the SGD hole SH is removed, and a semiconductor material is filled in the space. The insulating layer 42, the semiconductor layer 41, the core member 40, and the semiconductor material that remain in a layer above the insulating layer 58 are removed by, for example, CMP. The semiconductor material that remains in the SGD hole SH by the present process corresponds to the semiconductor portion 44. In this manner, a structure corresponding to the memory pillar MP is formed in the SGD hole SH.

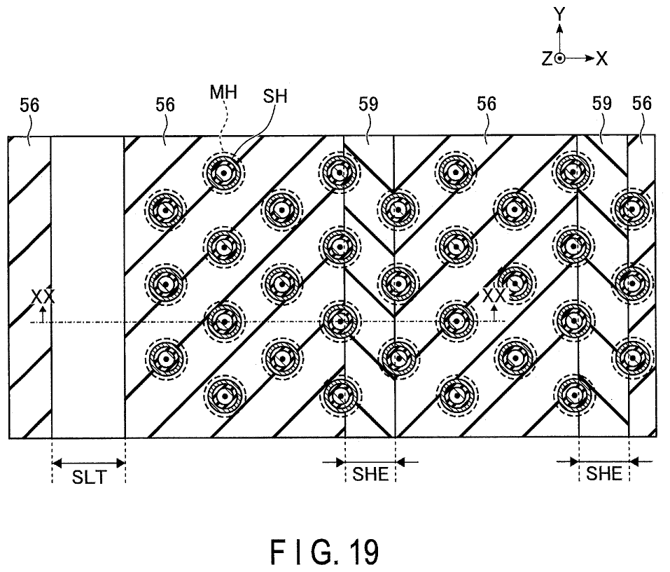

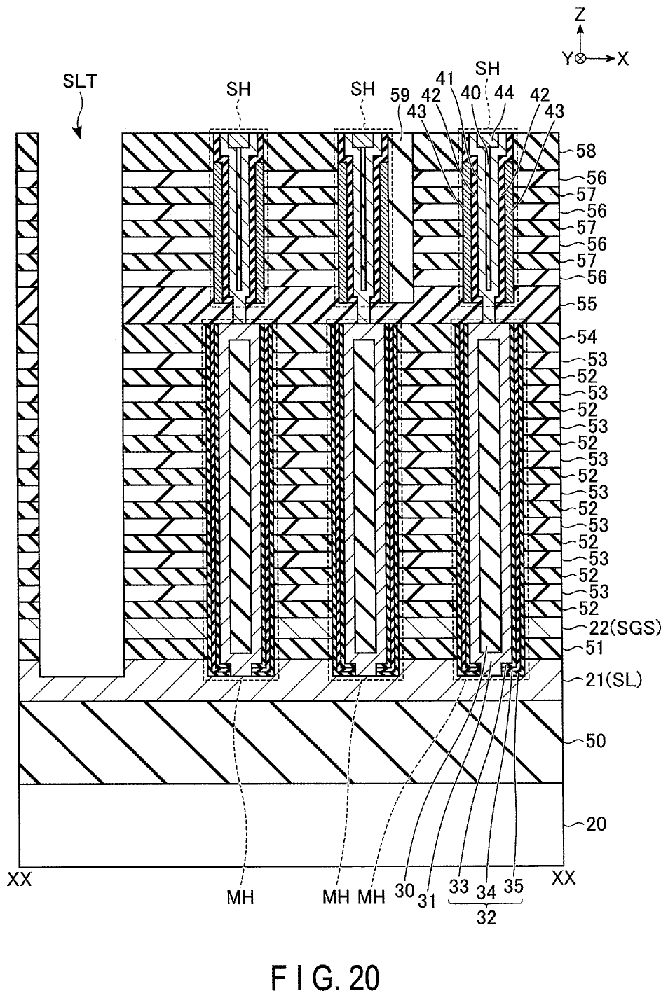

Next, the processing of step S109 is performed to form the slit SLT in the manners shown in FIG. 19 and FIG. 20. Specifically, first, a mask in which regions corresponding to the slits SLT are opened is formed by photolithography, etc. Then, the slit SLT is formed by anisotropic etching using the formed mask.

The slit SLT formed in the present process divides each of the insulating layers 51, 52, 54, 55, 57 and 58, the sacrificial members 53 and 56, and the conductive layer 22. The bottom part of the slit SLT stops, for example, in a layer in which the conductive layer 21 is provided. The bottom part of the slit SLT may at least reach the layer in which the conductive layer 21 is formed. The anisotropic etching in the present process is, for example, RIE.

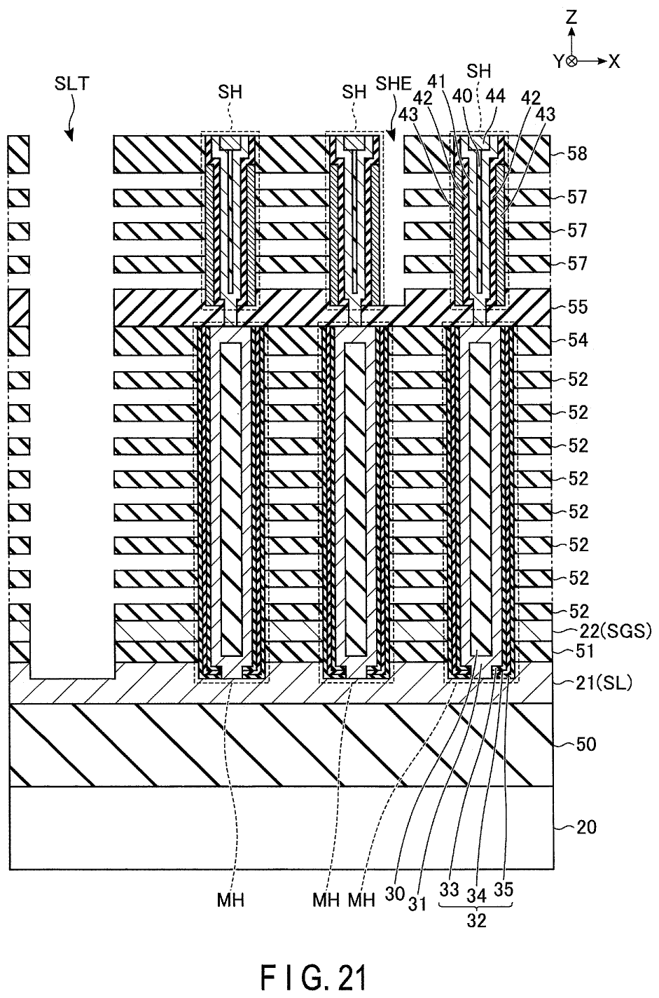

Next, the processing of step S110 is performed so as to perform replacement processing of the word line portion and the select gate line portion. Specifically, as shown in FIG. 21, first, the surfaces of the conductive layers 21 and 22 exposed in the slit SLT are oxidized to form an oxide protective film (not shown). Subsequently, the sacrificial members 53, 56, and 59 are selectively removed by, for example, wet etching by hot phosphoric acid. The structure from which the sacrificial members 53, 56, and 59 are removed maintains its three-dimensional structure by the plurality of memory pillars MP, etc.

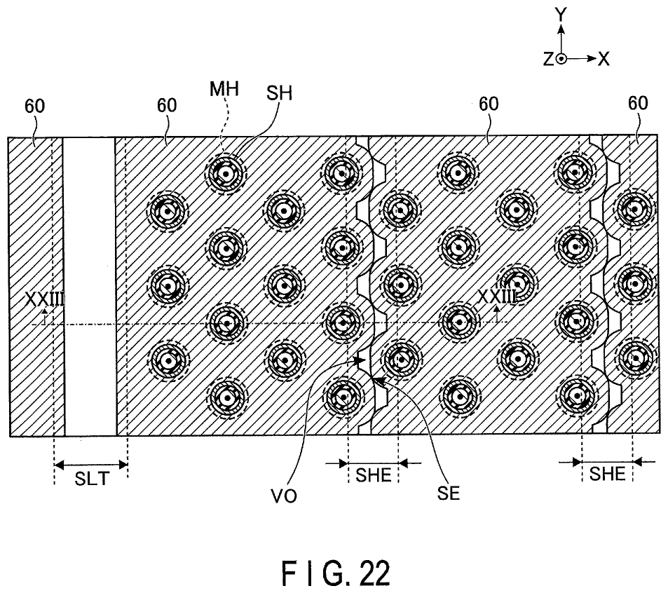

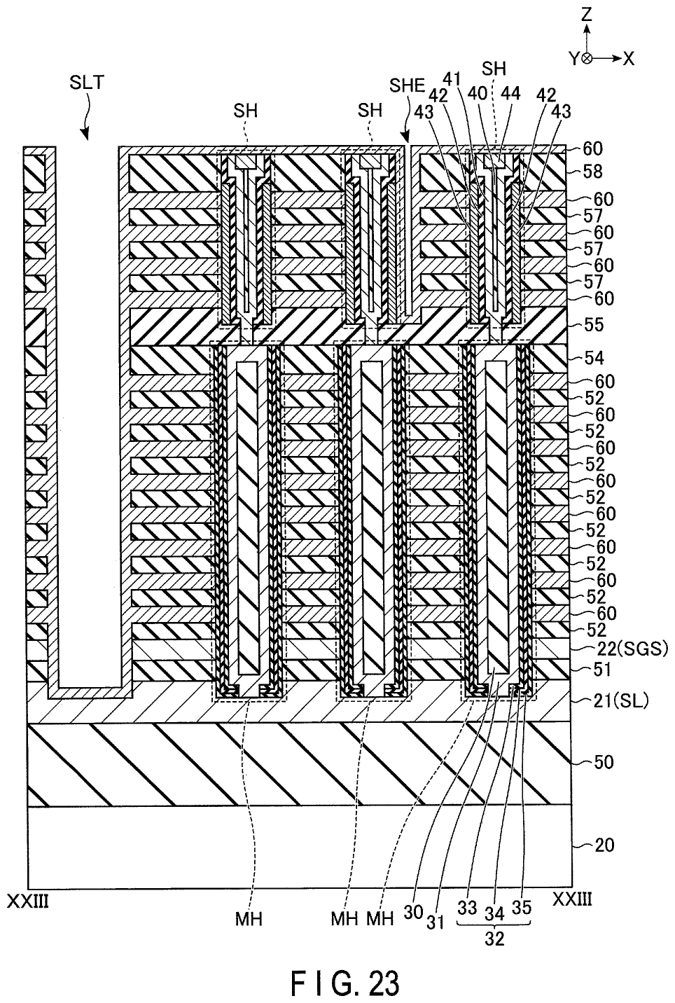

As shown in FIG. 22 and FIG. 23, a conductor 60 is filled in the space left by removal of the sacrificial members 53 and 56. Here, in the space left by removal of the sacrificial member 53, the conductor 60 is filled via the slit SLT, and, in the space left by removal of the sacrificial member 56 between the neighboring slits SHE, the conductor 60 is filled via the slits SHE.

For example, the conductor 60 grows from portions exposed via the slits SLT and SHE, such as the side surface of the memory pillar MP. Therefore, depending on the thickness in which the conductor 60 is formed, a seam SE may be formed on the conductor 60 formed between the neighboring memory pillars MP. In the present process, a void VO is likely to remain at least in the vicinity of the center of a triangle formed by three adjacent memory pillars MP in a cross-section parallel to the surface of the semiconductor substrate 20. In the present process, for example, CVD is used.

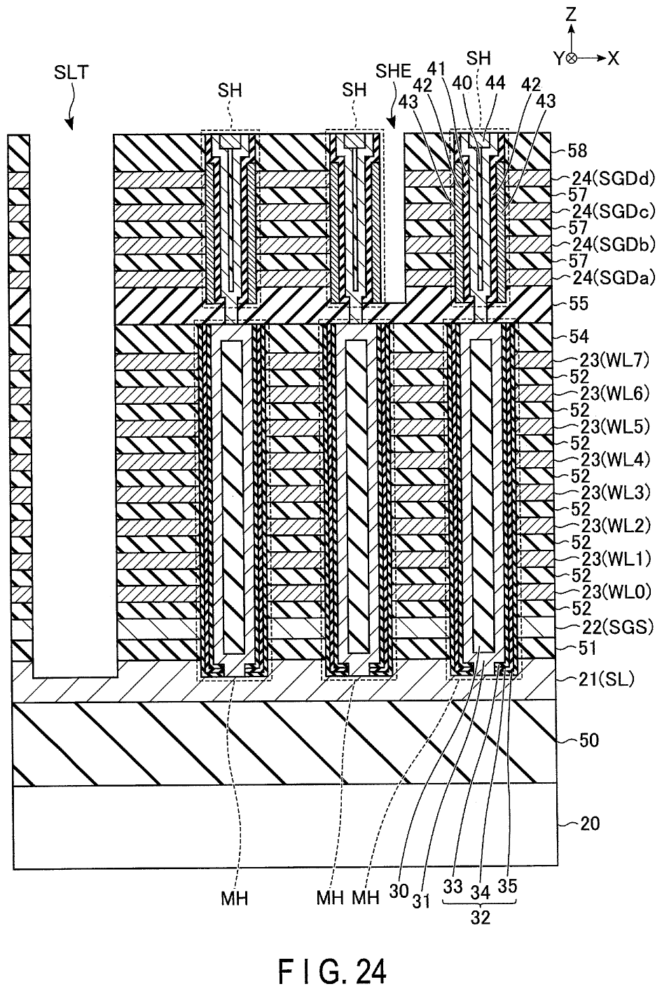

Subsequently, as shown in FIG. 24, the conductive layer 60 formed in the slits SLT and SHE and on the upper surface of the insulating layer 58 is removed by etchback processing. Here, in the slit SHE, the etching progresses from portions of the void VO and the seam SE. In the present process, the conductor 60 formed on neighboring wiring layers is divided in at least each of the slits SLT and SHE.

In this manner, a plurality of conductive layers 23 that correspond to each of the word lines WL0 to WL7, and a plurality of conductive layers 24 that correspond to the select gate line SGD are formed. The conductive layers 23 and 24 formed in the present process may include a barrier metal. In this case, when forming the conductor after removing the sacrificial members 53, 56, and 59, for example, a tungsten (W) is formed after titanium nitride (TiN) is formed as the barrier metal.

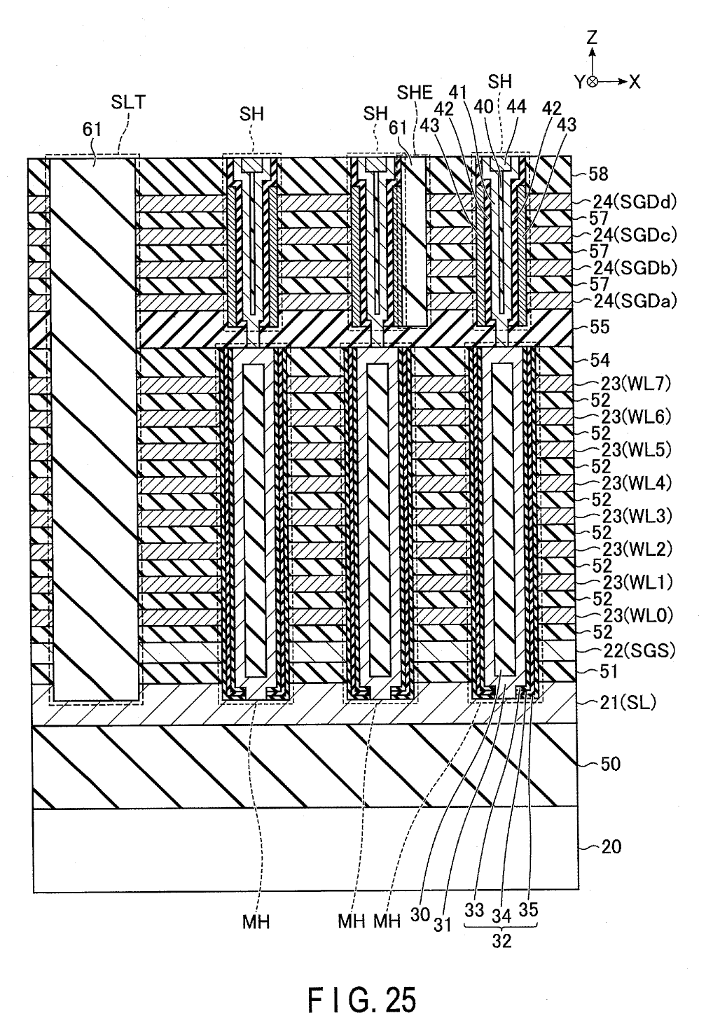

Next, the processing of step S111 is performed to form an insulator 61 in the slits SLT and SHE in the manner shown in FIG. 25. Specifically, the insulator 61 is formed to fill the slits SLT and SHE above the insulating layer 58. The insulator 61 formed in a layer above the insulating layer 58 is removed by, for example, CMP. The insulator 61 includes, for example, silicon oxide (SiO₂).

By the manufacturing process of the semiconductor memory device 1 according to the first embodiment explained above, each of the memory pillars MP, and the source lines SL, the word lines WL, and the select gate lines SGS and SGD coupled to the memory pillars MP are formed. The manufacturing process explained above is merely an example; therefore, other processes may be inserted between each manufacturing process, or the order of the manufacturing processes may be changed in a range that would not cause problems.

[1-3] Advantageous Effects of First Embodiment

According to the semiconductor memory device 1 of the first embodiment explained above, the storage capacity per unit area can be increased while reducing manufacturing costs of the semiconductor memory device 1. Advantageous effects of the semiconductor memory device 1 according to the first embodiment will be explained in detail below.

In a semiconductor memory device in which memory cells are three-dimensionally stacked, for example, plate-like wirings used as word lines WL are stacked, and a structure for functioning as a memory cell transistor MT is formed in a memory pillar that penetrates the stacked wirings. Furthermore, in the semiconductor memory device, for example, upper plate-like wirings used as a select gate line SGD through which the memory pillars penetrate are formed in a similar manner as the word lines WL, and the operation in page units is realized by appropriately dividing the select gate line SGD. In order to increase the storage capacity per unit area of such semiconductor memory device, it is preferable to increase a positional density of the memory pillars.

However, in the case of simply increasing the positional density of the memory pillars, it becomes difficult to form the slits SHE for dividing the select gate line SGD without overlapping the memory pillars MP arranged with a high density. In the case where the slits SHE and the memory pillars MP come in contact, variations in the characteristics of the select transistor ST1 increase, which may render the operation unstable.

In contrast, in the semiconductor memory device 1 according to the first embodiment, a cylindrical conductive layer 43 is provided in the memory pillar MP. The conductive layer 43 is, for example, a silicon doped with a highly-concentrated impurity, and is used as a gate electrode of the select transistor ST1. The conductive layer 43 is electrically coupled to a corresponding select gate line SGD (conductive layer 24). In the manufacturing process of the semiconductor memory device 1 according to the first embodiment, the memory pillar MP is formed after the slit SHE is formed.

Therefore, since the conductive layer 43 formed in the memory pillar MP is not affected when the slit SHE is being processed, variations in the conductive layer 43 per memory pillar MP may be reduced. In other words, in the manufacturing method of the semiconductor memory device 1 according to the first embodiment, it is possible to make the area of the conductive layer 43 (a gate electrode) surrounding the semiconductor layer 41 (a channel) and the insulating layer 42 (a gate insulating film) in each select transistor ST1 uniform.

As a result, in the semiconductor memory device 1 according to the first embodiment, the slit SHE and the memory pillar MP can overlap each other, which can reduce variations in the characteristics of the select transistor ST1. Accordingly, in the semiconductor memory device of the first embodiment, the memory pillars MP can be arranged with high density (for example, the memory pillars can be arranged at approximately equal pitches), which can increase the storage capacity per unit area.

Furthermore, in the semiconductor memory device 1 according to the first embodiment explained above, three slits SHE are formed between the neighboring slits SLT where the memory pillars MP are arranged with high density. In the case of forming two or more slits SHE between the neighboring slits SLT, since the slits SHE block the region between the two slits SHE, etching cannot be performed in the lateral direction via the slits SLT. That is, in the region between the two slits SHE, replacement processing cannot be performed via the slit SLT.

In contrast, in the manufacturing method of the semiconductor memory device 1 according to the first embodiment, the memory pillars MP are formed after the sacrificial members 59 are filled in the slits SHE, and replacement processing is performed via the slits SLT and SHE.

Specifically, among the sacrificial members formed in each wiring layer corresponding to the word lines WL and the select gate line SGD, the sacrificial members formed between the slits SLT and SHE are removed by wet etching via the slits SLT. On the other hand, among the sacrificial members formed in each wiring layer, the sacrificial members formed between the two slits SHE are removed by wet etching via the slits SHE.

In the space left by removal of the sacrificial members between the slits SLT and SHE, the conductor is filled via the slit SLT, and, in the space left by removal of the sacrificial members between the two slits SHE, the conductor is filled via the slits SHE. Furthermore, in the semiconductor memory device 1 according to the first embodiment, a plurality of wiring layers that correspond to the select gate line SGD are prepared. By designing each of these wiring layers with a low thickness, each of the wiring layers can be filled via the slits SHE.

In the process of filling the space of the wiring layers corresponding to the select gate line SGD, there is a possibility that the slits SHE may close. However, in the manufacturing method of the semiconductor memory device 1 according to the first embodiment, even in the case where a part of the slit SHE closes, by progressing the etching via the seam and space (void) formed in the slit SHE, the stacked select gate lines SGDa, SGDb, SGDc, and SGDd can be divided per string unit SU.

In the manner mentioned above, the manufacturing method of the semiconductor memory device 1 according to the first embodiment is capable of performing the replacement processing of the word lines WL and the select gate line SGD altogether, and is capable of performing the replacement processing of the select gate line SGD between the two slits SHE by using the slits SHE. As a result, the use of manufacturing method of the semiconductor memory device 1 according to the first embodiment enables the number of manufacturing processes to be lower than that in the case where the word lines WL and the select gate line SGD are formed separately, thereby reducing production costs.

### [2] Second Embodiment

A semiconductor memory device 1 according to a second embodiment has a structure in which forming the SGD hole SH is omitted with respect to the structure of the semiconductor memory device 1 according to the first embodiment. In the following, the semiconductor memory device 1 according to the second embodiment will be explained regarding points that are different from the first embodiment.

[2-1] Structure of Memory Cell Array 10

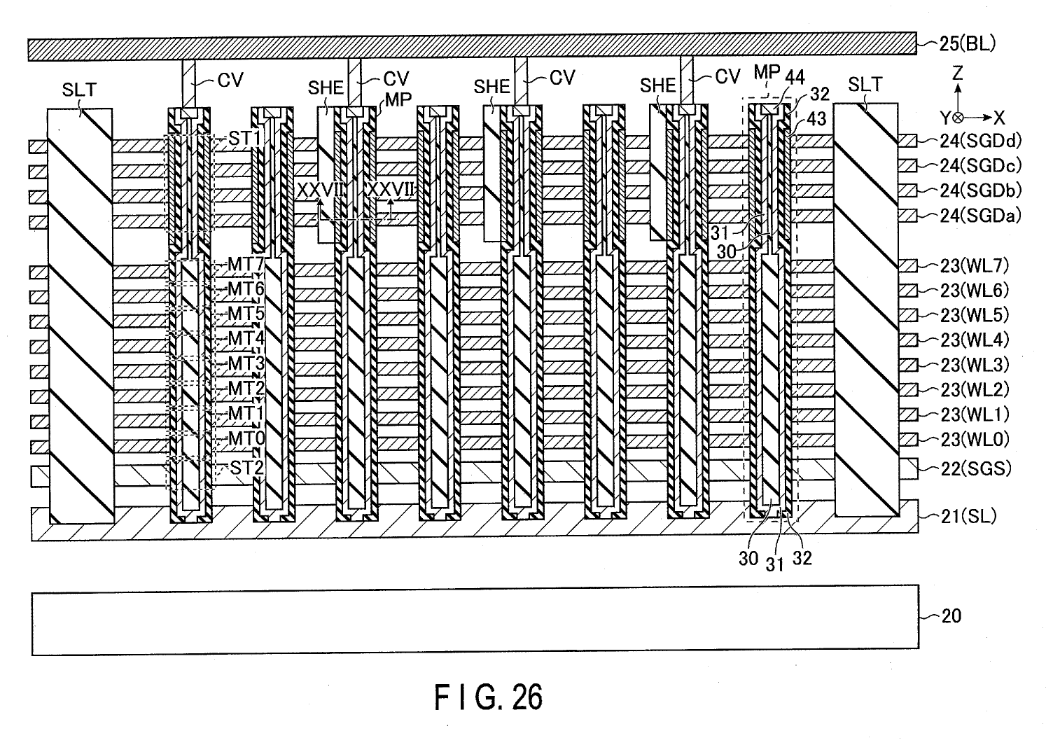

FIG. 26 shows an example of a cross-sectional structure of a memory cell array 10 included in the semiconductor memory device 1 according to the second embodiment. As shown in FIG. 26, a structure of the memory cell array 10 in the second embodiment is different from the structure of the memory cell array 10 in the first embodiment explained with reference to FIG. 4 regarding the structure of a memory pillar MP. Specifically, in the memory pillar MP of the second embodiment, a core member 30, a semiconductor layer 31, a stacked film 32, a conductive layer 43, and a semiconductor portion 44 are provided in a memory hole MH.

The upper ends of the core member 30, the semiconductor layer 31, and the stacked film 32 are included in a layer above an uppermost conductive layer 24. The stacked film 32 contacts the inner wall of the conductive layer 43. The semiconductor layer 31 and the stacked film 32 include portions provided along the conductive layer 43. The semiconductor portion 44 contacts the semiconductor layer 31 through its side surface, and contacts the core member 30 and the semiconductor layer 31 through its bottom surface. A part of the side surface of stacked film 32 and the side surface of the conductive layer 43 are respectively in contact with the inner wall of the memory hole MH. That is, a part of the side surface of the stacked film 32 and the side surface of the conductive layer 43 are aligned.

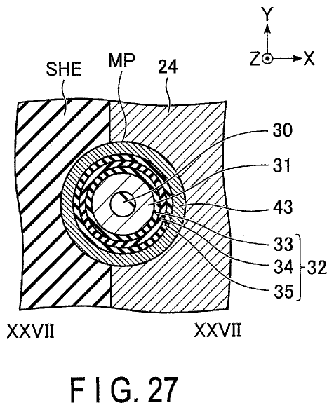

FIG. 27 is a cross-sectional view taken along line XXVII-XXVII of FIG. 26, and shows an example of a cross-sectional structure of the memory pillar MP in the semiconductor memory device 1 according to the second embodiment. More specifically, FIG. 27 shows a cross-sectional structure of the memory pillar MP in a layer that is parallel to the surface of a semiconductor substrate 20 and that includes a conductive layer 24. Furthermore, in the region shown in FIG. 27, the memory pillar MP and a slit SHE are in contact.

As shown in FIG. 27, in the layer including the conductive layer 24, for example, the core member 30 is provided at the center of the memory hole MH. The semiconductor layer 31 surrounds the side surface of the core member 30. The stacked film 32 surrounds the side surface of the semiconductor layer 31. Specifically, a tunnel insulating film 33 surrounds the side surface of the semiconductor layer 31. An insulating film 34 surrounds the side surface of the tunnel insulating film 33. A block insulating film 35 surrounds the side surface of the insulation film 34. The conductive layer 43 surrounds the side surface of the stacked film 32. Specifically, the conductive layer 43 surrounds the side surface of the block insulating film 35. The side surface of the conductive layer 43 contacts, for example, each of the conductive layer 24 and the slit SHE. Since the other structures of the semiconductor memory device 1 according to the second embodiment are similar to those of the semiconductor memory device 1 according to the first embodiment, explanations thereof will be omitted.

[2-2] Manufacturing Method of Semiconductor Memory Device 1

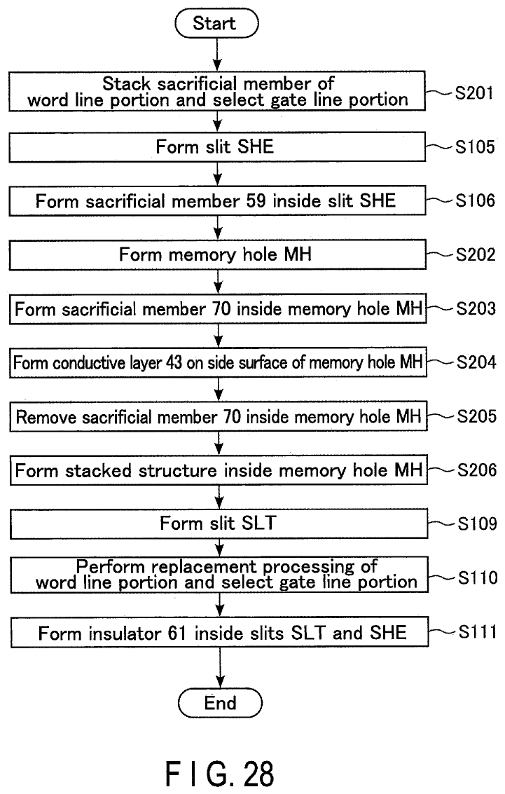

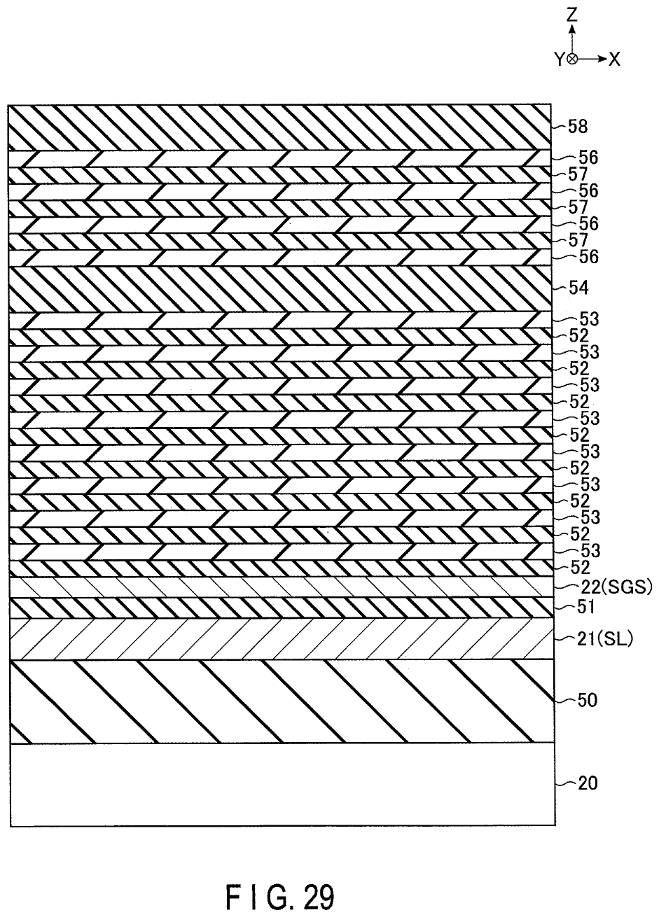

In the following, an example of a series of manufacturing processes from forming stacked structures corresponding to word lines WL to forming slits SLT in the semiconductor memory device 1 according to the second embodiment will be explained with reference to FIG. 28 as needed. FIG. 28 is a flowchart showing an example of a manufacturing method of the semiconductor memory device 1 according to the second embodiment. Each of FIG. 29 to FIG. 36 shows an example of a cross-sectional structure including a structure corresponding to the memory cell array 10 in the manufacturing process of the semiconductor memory device 1 according to the second embodiment.

First of all, the processing of step S201 is performed, in which a sacrificial member 53 of a word line portion and a sacrificial member 56 of a select gate line portion are stacked in the manner shown in FIG. 29. Specifically, first, an insulating layer 50, a conductive layer 21, an insulating layer 51, and a conductive layer 22 are stacked in sequence on the semiconductor substrate 20, and an insulating layer 52 and a sacrificial member 53 are alternately stacked on the conductive layer 22. An insulating layer 54 is formed on the uppermost sacrificial member 53, and a sacrificial member 56 and an insulating layer 57 are alternately stacked on the insulating layer 54. Then, an insulating layer 58 is formed on the uppermost sacrificial member 56.

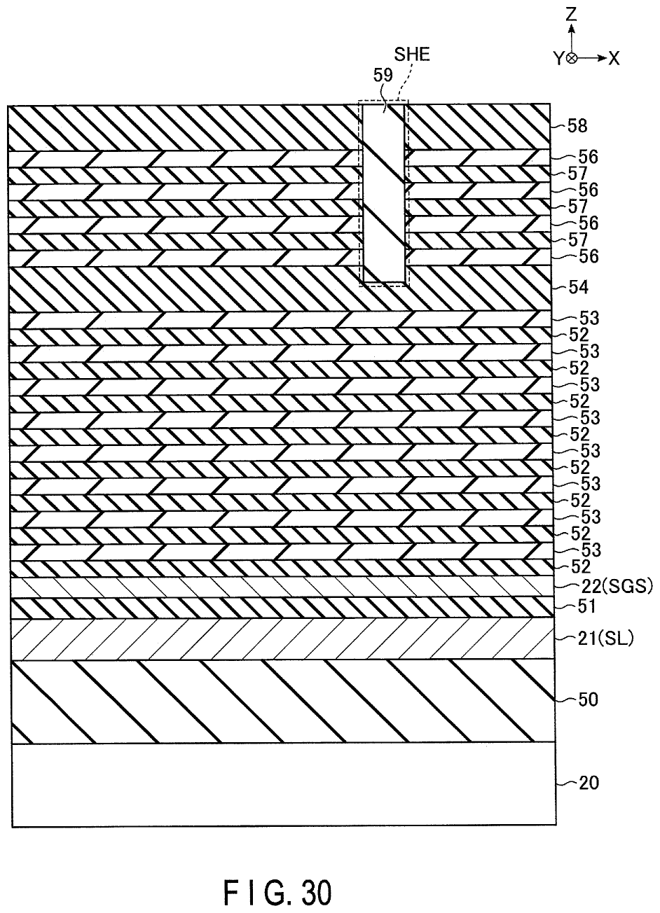

Next, the processing of steps S105 and S106 explained in the first embodiment is performed, and a slit SHE as shown in FIG. 30 is formed, and a sacrificial member 59 is formed in the slit SHE. The slit SHE formed in the present process divides each of the insulating layers 57 and 58, and the sacrificial member 56. The bottom part of the slit SHE stops in a layer in which the insulating layer 54 is provided. The slit SHE divides at least all of the sacrificial members 56.

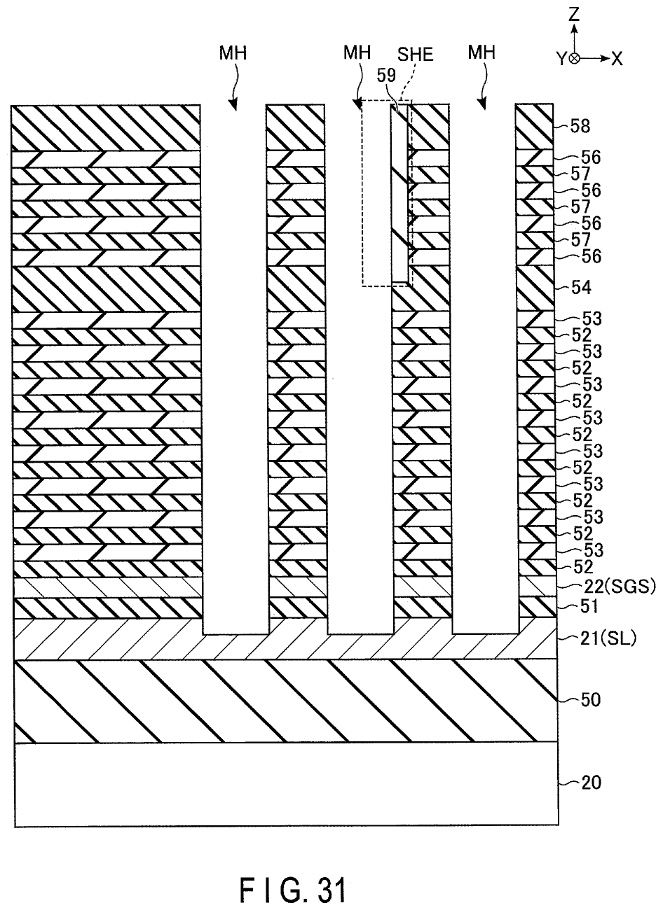

Next, the processing of step S202 is performed to form the memory hole MH in the manner shown in FIG. 31. The method of forming the memory hole MH and the planar layout thereof are the same as those in the first embodiment. The memory hole MH formed in the present process penetrates each of the insulating layers 51, 52, 54, 57, and 58, the sacrificial members 53 and 56, and the conductive layer 22. The bottom part of the memory hole MH stops, for example, in the conductive layer 21.

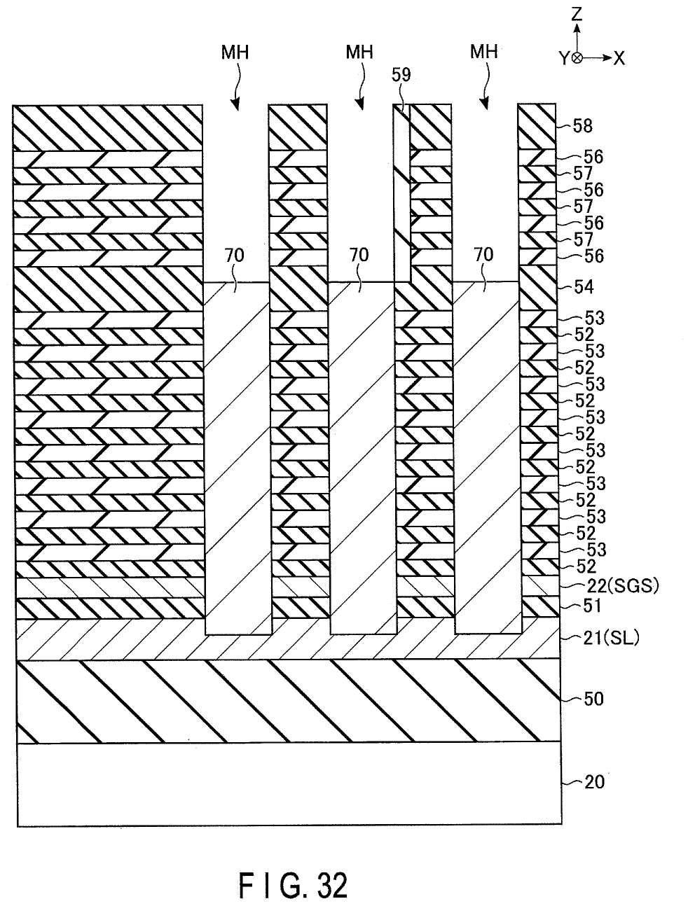

Next, the processing of step S203 is performed to form a sacrificial member 70 in the memory hole MH in the manner shown in FIG. 32. Specifically, first, the sacrificial member 70 is formed, and, for example, the sacrificial member 70 is filled in the memory hole MH. Subsequently, etchback processing is performed to remove the sacrificial member 70 formed on the upper part of the memory hole MH, and the sacrificial member 70 is processed to a desired height in the memory hole MH. The upper surface of the sacrificial member 70 formed by the present process is included in a layer in which the insulating layer 54 is formed.

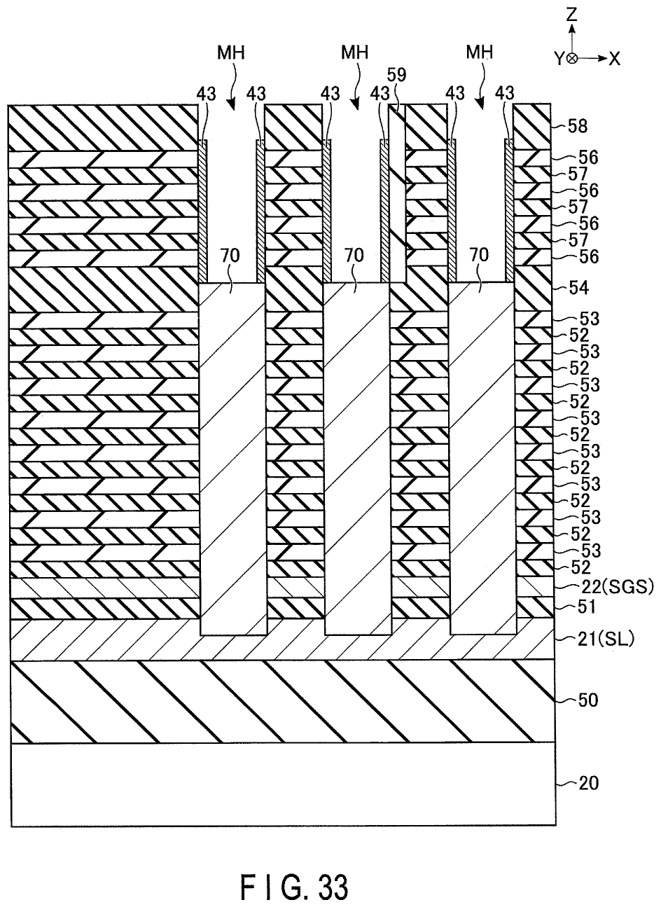

Next, the processing of step S204 is performed to form the conductive layer 43 on the side surface of the memory hole MH in the manner shown in FIG. 33. Specifically, first, for example, the conductive layer 43 is formed on the side surface and the bottom surface of the opening of the memory hole MH. Subsequently, etchback processing is performed to remove the conductive layer 43 formed on the bottom part of the opening of the memory hole MH, and the conductive layer 43 in the memory hole MH is processed to a desired height.

Furthermore, in the present process, a sacrificial member may be temporarily filled in the memory hole MH in order to adjust the height of the conductive layer 43. In this case, for example, the sacrificial member is filled after the conductive layer 43 formed on the bottom part of the opening of the memory hole MH is removed. After this sacrificial member is etched back to a desired height, the conductive layer 43 that is exposed in the memory hole MH is removed.

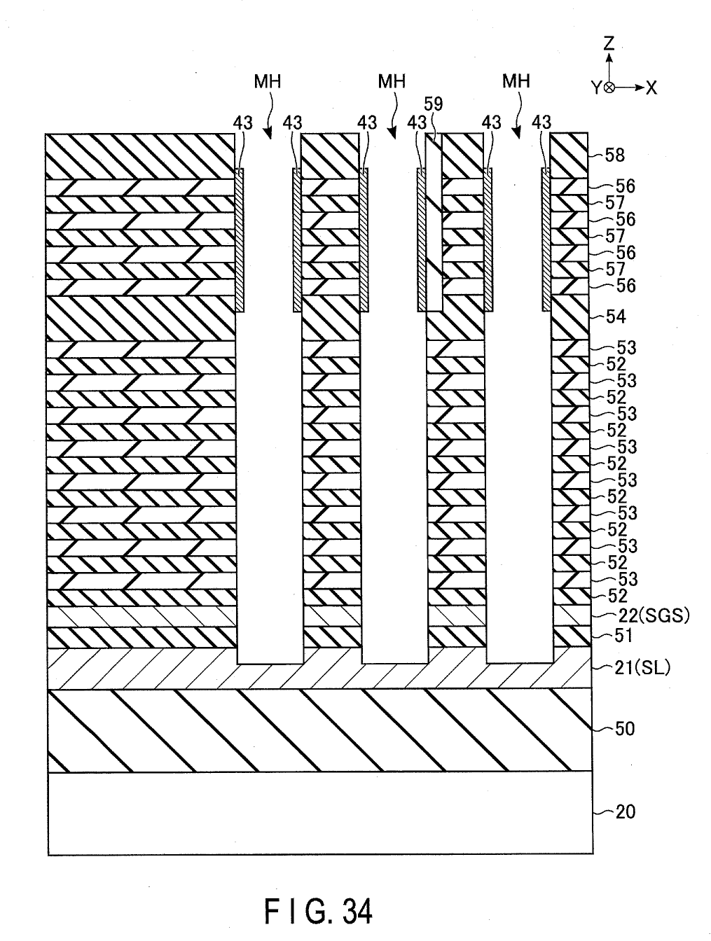

Next, the processing of step S205 is performed to remove the sacrificial member 70 in the memory hole MH in the manner shown in FIG. 34. In the present process, for example, wet etching is used. By the present process, a structure in which the conductive layer 43 remains in the memory hole MH is formed.

Next, the processing of step S206 is performed to form a stacked structure in the memory hole MH. Specifically, the stacked film 32 is formed on the side surface and the bottom surface of the memory hole MH, and on the upper surface of the insulating layer 58. That is, the block insulating film 35, the insulating film 34, and the tunnel insulating film 33 are formed in sequence.

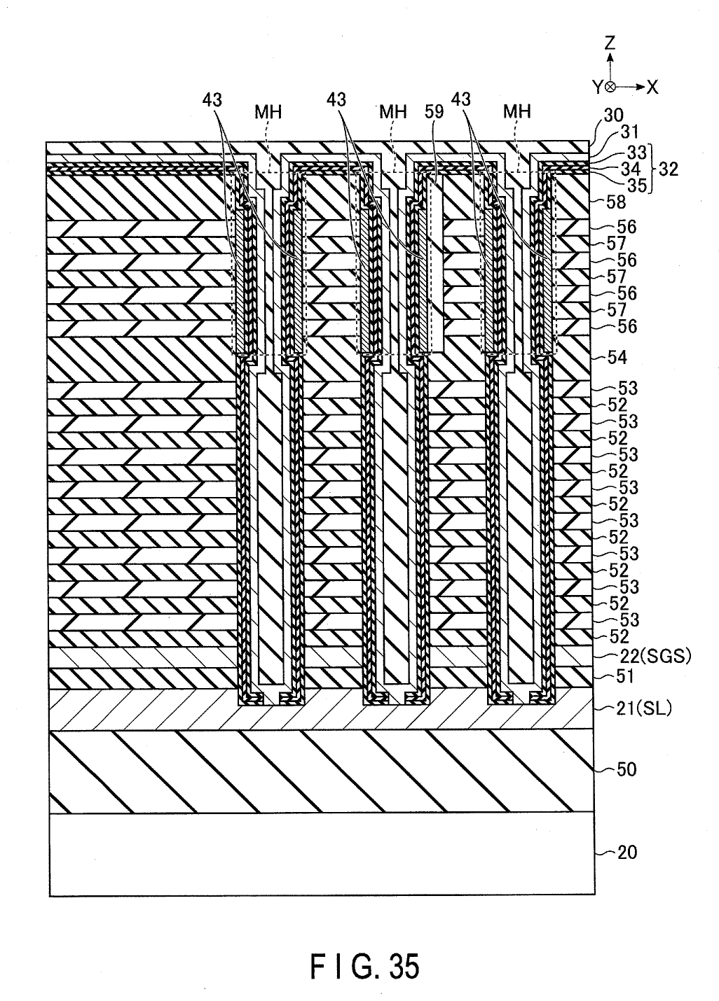

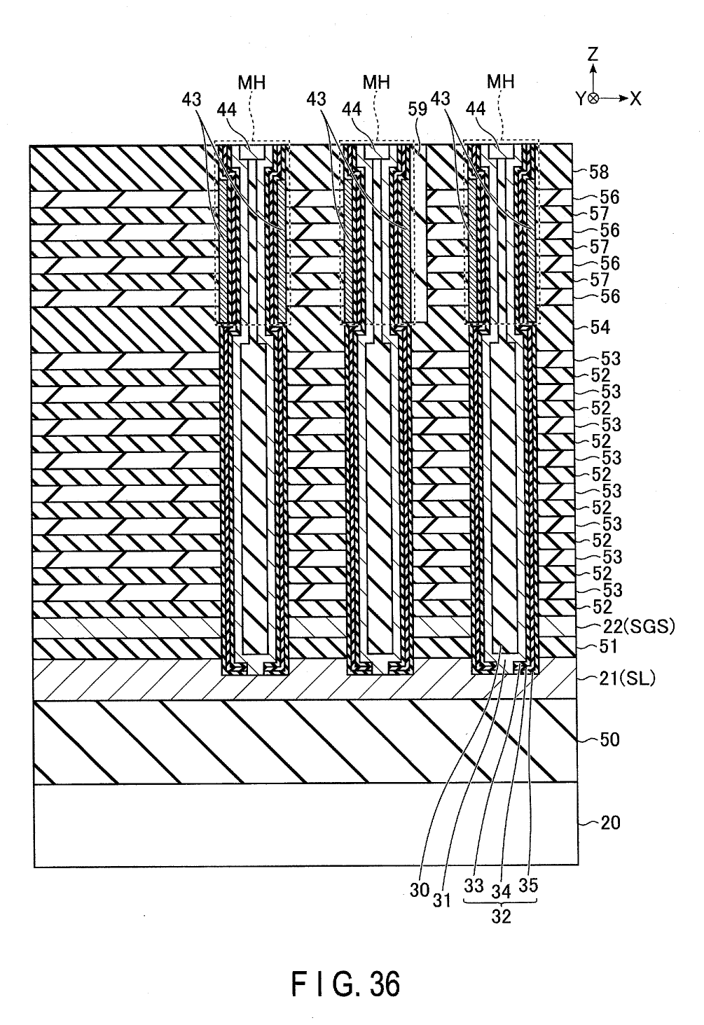

After the stacked film 32 on the bottom part of the memory hole MH is removed, the semiconductor layer 31 and the core member 30 are formed in sequence, and the core member 30 is filled in the memory hole MH in the manner shown in FIG. 35. Then, a part of the core member 30 formed on the upper part of the memory hole MH is removed in the manner shown in FIG. 36, and a semiconductor material is filled in the space. Subsequently, the stacked film 32, the semiconductor layer 31, and the semiconductor material that remain in a layer above the insulating layer 58 are removed by, for example, CMP. The semiconductor material that remains in the memory hole MH by the present process corresponds to the semiconductor portion 44.

Next, the processing of steps S109 to S111 explained in the first embodiment is performed in sequence. Since the details of these processes are the same as those of the first embodiment, explanations thereof will be omitted. In the above manner, each of the memory pillars MP, and the source lines SL, the word lines WL, and the select gate lines SGS and SGD coupled to the memory pillars MP are formed in the semiconductor memory device 1 according to the second embodiment. The manufacturing process explained above is merely an example; therefore, other processes may be inserted between each manufacturing process, or the order of the manufacturing processes may be changed in a range that would not cause problems.

[2-3] Advantageous Effects of Second Embodiment

In a memory pillar MP that is obtained by connecting a pillar corresponding to the memory hole MH and a pillar corresponding to the SGD hole SH in the manner of the first embodiment, the memory hole MH may be misaligned with the SGD hole SH when forming the SGD hole SH. Furthermore, a lithography process is performed respectively when forming the memory hole MH and forming the SGD hole SH.

In contrast, in the manufacturing method of the semiconductor memory device 1 according to the second embodiment, a configuration corresponding to the memory cell transistors MT and a configuration corresponding to the select transistor ST1 including the semiconductor layer 43 are formed in a memory hole MH formed by performing a lithography process once.

Accordingly, in the manufacturing method of the semiconductor memory device 1 according to the second embodiment, the memory pillar MP would not be misaligned. That is, in the manufacturing method of the semiconductor memory device 1 according to the second embodiment, while increasing the storage capacity per unit area by arranging the memory pillars MP with high density, the occurrence of defects caused by the memory pillar MP can be reduced, and the yield can be improved. Furthermore, in the manufacturing method of the semiconductor memory device 1 according to the second embodiment, the manufacturing processes can be reduced further than in the case of the first embodiment, and the manufacturing costs can be reduced.

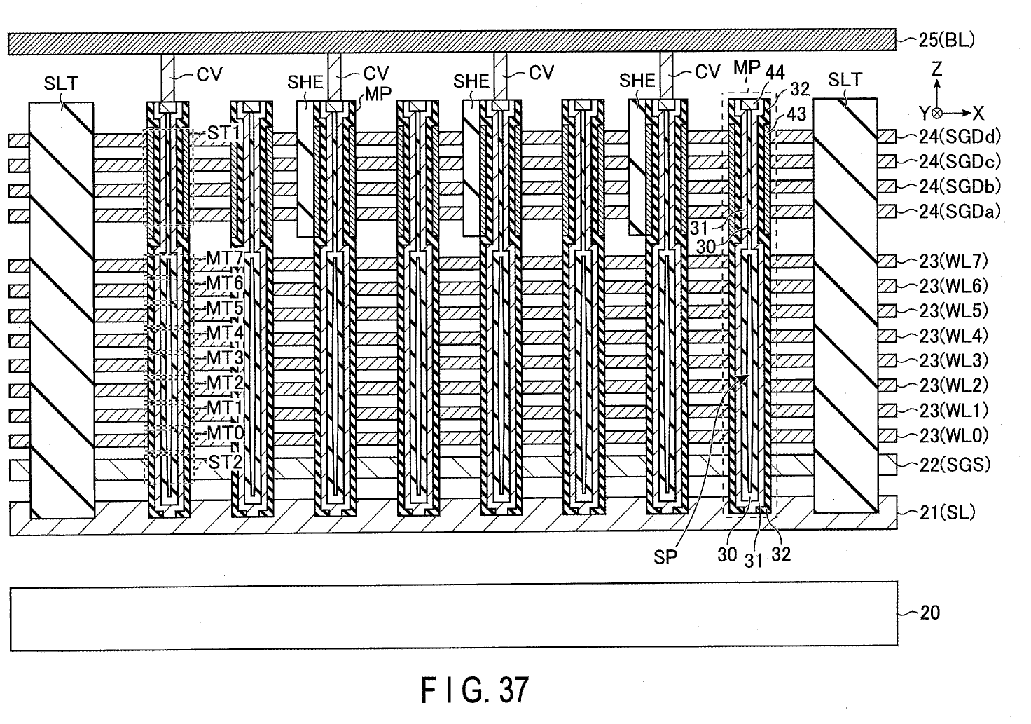

In the above explanations, the case of filling the memory pillar completely with the core member 30 has been exemplified; however, it is not limited thereto. FIG. 37 shows an example of a cross-sectional structure of a memory cell array 10 included in the semiconductor memory device 1 according to a modified example of the second embodiment. As shown in FIG. 37, the memory pillar MP does not have to be completely filled with the core member 30, and may include space SP. The space SP is defined by the core member 30. A region in which the space SP is formed is, for example, a portion facing wiring layers on which stacked word lines WL are formed. Even in the case where the space SP is included in the memory pillar MP in such manner, the semiconductor memory device 1 according to the second embodiment can operate in the same manner as in the case where there is no space SP in the memory pillar MP.

### [3] Other Modified Examples, etc.

A semiconductor memory device according to an embodiment includes a plurality of first conductive layers, a plurality of second conductive layers, and a pillar. The first conductive layers are provided above a substrate. The first conductive layers are stacked apart from each other in a first direction. The second conductive layers are provided above the first conductive layers. The second conductive layers are stacked apart from each other in the first direction. The pillar is penetrating the first conductive layers and the second conductive layers. The pillar includes a first semiconductor layer, a second semiconductor layer, a third conductive layer, and a gate insulating film. The first semiconductor layer is extending in the first direction and facing the first conductive layers. The second semiconductor layer is extending in the first direction and facing the second conductive layers. The third conductive layer is extending in the first direction and between the second semiconductor layer and the second conductive layers. The gate insulating film is provided between the second semiconductor layer and the third conductive layer. An intersecting portion of the pillar and one of the first conductive layers functions as a memory cell transistor. An intersecting portion of the pillar and one of the second conductive layers functions as a select transistor. The third conductive layer is electrically coupled to the second conductive layers. In this manner, the storage capacity per unit area of the semiconductor memory device can be increased. Furthermore, the manufacturing costs of the semiconductor memory device can be reduced.

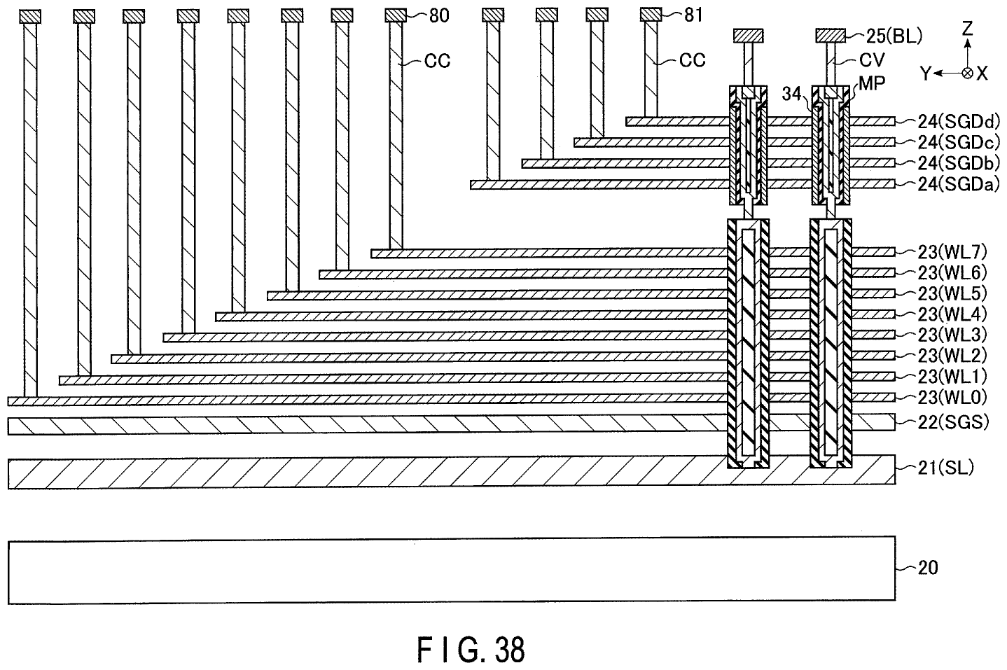

In the above embodiments, for example, contacts shown in FIG. 38 are coupled to the stacked select gate lines SGDa, SGDb, SGDc, and SGDd. FIG. 38 shows an example of a cross-sectional configuration of the memory cell array 10 included in the semiconductor memory device 1 according to the first embodiment, and a region that is utilized to couple the word lines WL and the select gate line SGD to the row decoder module 15 is extracted. As shown in FIG. 38, for example, the end portions of the stacked word lines WL (conductive layers 23) are formed in a stepped fashion. For example, the end portions of the stacked select gate lines SGDa, SGDb, SGDc, and SGDd (conductive layers 24) are formed in a stepped fashion in the same manner as the word lines WL.

Each of the end portions of the stacked conductive layers 23 has a terrace portion that does not overlap with the above conductive layers 23. Each of the end portions of the stacked conductive layers 24 has a terrace portion that does not overlap with the above conductive layers 24. On the terrace portion of each of the conductive layers 23, a contact CC is provided to electrically couple the conductive layer 23 to a corresponding conductive layer 80. On the terrace portion of each of the conductive layers 24, a contact CC is provided to electrically couple the conductive layer 24 to a corresponding conductive layer 81. The conductive layers 80 and 81 are electrically coupled to the row decoder module 15. For example, the conductive layers 80 and 81 are formed on layers above the conductive layer 25. In each of the blocks BLK, four conductive layers 81 that correspond to the select gate lines SGDa to SGDd are electrically coupled via conductive layers 43 in the memory pillar MP. In each of the blocks BLK, the conductive layers 81 corresponding to the select gate lines SGDa to SGDd of the same string unit SU may be short-circuited.

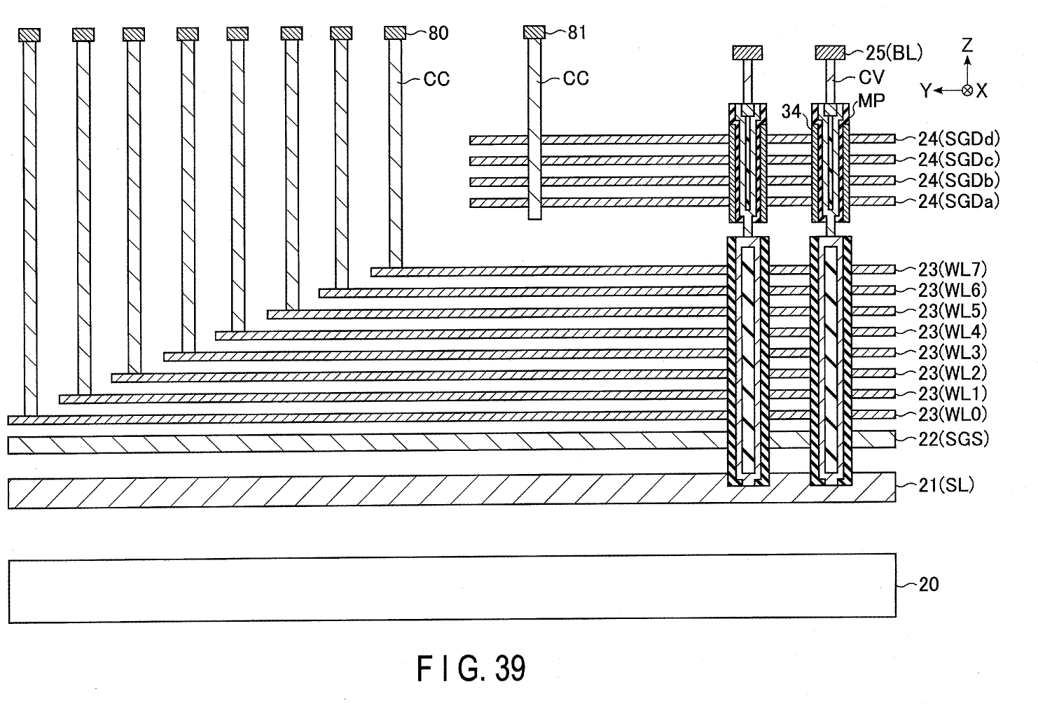

Furthermore, the end portions of the stacked select gate lines SGDa, SGDb, SGDc, and SGDd may have a structure as shown in FIG. 39. FIG. 39 shows an example of a cross-sectional structure of a memory cell array 10 included in a semiconductor memory device 1 according to a modified example of the first embodiment, and extracts the same region as that in FIG. 38. As shown in FIG. 39, the ends of the stacked select gate lines SGDa to SGDd (conductive layers 24) may be aligned.

In this case, for example, a contact CC penetrates the end region of each of the stacked conductive layers 24. The contact CC penetrating the conductive layers 24 is electrically coupled to stacked conductive layers 24 (select gate lines SGDa to SGDd). The upper end of the contact CC penetrating the conductive layer 24 is electrically coupled to a corresponding conductive layer 81, and the lower end thereof is included in, for example, a layer between an uppermost conductive layer 23 and a lowermost conductive layer 24.

In an example shown in FIG. 38, the contacts CC coupled to the conductive layers 24 may penetrate the conductive layers 24, or may be electrically coupled to a plurality the conductive layers 24. The contacts CC coupled to the conductive layers 24 should at least not contact the uppermost layer of the conductive layer 23 (word lines WL). In an example shown in FIG. 39, the contact CC penetrating the conductive layers 24 may at least be electrically coupled to the stacked conductive layers 24, or the lower end of the contact CC may contact the lowermost conductive layer 24. Furthermore, in an example shown in FIG. 39, the contact CC coupled to the select gate line SGD and the contacts CC coupled to the word lines WL may be formed by separate processes. The structures of the memory cell array 10 shown in FIG. 38 and FIG. 39 may be formed similarly also in the semiconductor memory device 1 according to the second embodiment.

In the above embodiments, the memory cell array 10 may also have a different structure. For example, the memory pillar MP may have a structure in which a plurality of pillars are connected in the Z direction. In this case, for example, the memory pillar MP may have a structure in which a pillar penetrating the conductive layer 24 (select gate line SGD) and the plurality of conductive layers 23 (word lines WL) is connected to a pillar penetrating the plurality of conductive layers 23 (word lines WL) and a conductive layer 22 (select gate line SGS). Furthermore, the memory pillar MP may include a plurality of pillars that penetrate a plurality of conductive layers 23.

In the first embodiment, a case in which centers of the corresponding memory hole MH and SGD hole SH overlap has been exemplified; however, it is not limited thereto. The centers of the corresponding memory hole MH and SGD hole SH may change in accordance with the positional relationship of the slits SLT and SHE.

In the above embodiments, an example of a case in which the semiconductor memory device 1 has a structure in which a circuit, such as the sense amplifier module 16, is provided below the memory cell array 10 has been explained; however, the structure is not limited thereto. For example, the semiconductor memory device 1 may have a structure in which the memory cell array 10 and the sense amplifier module 16 are formed on the semiconductor substrate 20. Furthermore, the semiconductor memory device 1 may have a structure in which a chip on which the sense amplifier module 16, etc. is provided and a chip on which the memory cell array 10 is provided are bonded together.

In the above embodiments, a structure in which the word line WL and the select gate line SGS are adjacent to each other, and the word line WL and the select gate line SGD are adjacent to each other has been explained; however, the structure is not limited thereto. For example, a dummy word line may be provided between the word line WL of the uppermost layer and the select gate line SGD. Similarly, a dummy word line may be provided between the word line WL of the lowermost layer and the select gate line SGS. Furthermore, in the case of a structure in which a plurality of pillars are connected, a conductive layer in the vicinity of the connection portion may be used as a dummy word line.

In the drawings referred to in the explanations of the above embodiments, a case in which the outer diameters of the memory hole MH and the SGD hole SH, etc. are made constant regardless of the stacked position has been exemplified; however, the diameters are not limited thereto. For example, the memory hole MH and the SGD hole SH may have a tapered shape or may have a shape in which the middle portion thereof is enlarged. Similarly, the slits SLT and SHE may also have a tapered shape or may have a shape in which the middle portion thereof is enlarged.

In the above embodiments, a case in which the conductive layer 21 and the semiconductor layer 31 are electrically coupled via the bottom part of the memory pillar MP has been exemplified; however, the embodiments are not limited thereto. The semiconductor layer 31 and the conductive layer 21 may also be electrically coupled via the side surface of the memory pillar MP. In this case, a structure is formed in which a part of the stacked film 32 formed on the side surface of the memory pillar MP is removed, and the semiconductor layer 31 and the conductive layer 21 come in contact via such part.

In the present specification, the term “couple” indicates electrical coupling, and does not exclude a case in which, for example, the coupling is made through another element. Furthermore, “electrical coupling” may also be performed via an insulator as long as an operation similar to that of the electrical coupling can be performed. For example, an insulator such as alumina (Al₂O₃) may be formed between the conductive layer 24 and the conductive layer 43 in the SGD hole SH. As long as it is a structure in which the change in voltage of the conductive layer 24 is associated with the change in voltage of the conductive layer 43, the conductive layer 24 and the conductive layer 43 may substantially be regarded as being electrically coupled.

“Continuously provided” indicates a matter of being formed by the same manufacturing process. A boundary is not formed on a portion that is continuously provided in a certain structural element. “Continuously provided” is synonymous with being a continuous film from a first portion to a second portion in a film or a layer. “Film thickness” indicates, for example, a difference between an inner diameter and an outer diameter of a structural element formed in the memory hole MH or the SGD hole SH. The “inner diameter” and the “outer diameter” respectively indicate an inner diameter and an outer diameter in a cross-section parallel to the semiconductor substrate 20.

In the present specification, “a facing portion” corresponds to portions of two adjacent structural elements in a direction parallel to the surface of the semiconductor substrate 20. For example, a portion of the semiconductor layer 31 facing the conductive layer 23 corresponds to a portion of the semiconductor layer 31 included in a layer in which the conductive layer 23 is formed. “Approximately the same thickness” indicates a layer (film) that is formed by the same manufacturing process, and also includes variations that are based on a film forming position.

“Columnar” in the present specification indicates a structure that is provided in a hole formed in the manufacturing process of the semiconductor memory device 1. The structures formed in the memory hole MH and the SGD hole SH may be referred to, respectively, as “pillars”. That is, the memory pillar MP in the first embodiment has a structure in which a pillar corresponding to the SGD hole SH is formed on a pillar corresponding to the memory hole MH.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first conductive layers provided above a substrate, the first conductive layers being stacked apart from each other in a first direction;
a plurality of second conductive layers provided above the first conductive layers, the second conductive layers being stacked apart from each other in the first direction; and
a pillar penetrating the first conductive layers and the second conductive layers, the pillar including a first semiconductor layer, a second semiconductor layer, a third conductive layer, and a gate insulating film, the first semiconductor layer extending in the first direction and facing the first conductive layers, the second semiconductor layer extending in the first direction and facing the second conductive layers, the third conductive layer extending in the first direction and being provided between the second semiconductor layer and the second conductive layers, and the gate insulating film being provided between the second semiconductor layer and the third conductive layer, wherein
an intersecting portion of the pillar and one of the first conductive layers functions as a memory cell transistor, and an intersecting portion of the pillar and one of the second conductive layers functions as a select transistor, and
the third conductive layer is electrically coupled to the second conductive layers.

2. The device of claim 1, further comprising a first slit that divides the second conductive layers, has an insulator formed therein, and contacts the third conductive layer.

3. The device of claim 2, further comprising second slits that divide the first conductive layers and the second conductive layers, have an insulator formed therein, and are adjacent in a second direction that intersects with the first direction, wherein
a plurality of the pillars and a plurality of the first slits arranged in the second direction are provided between the adjacent second slits.

4. The device of claim 3, wherein the pillars are arranged in approximately equal pitches.

5. The device of claim 1, wherein a space in the first direction between an uppermost first conductive layer and a lowermost second conductive layer is wider than a space in the first direction between neighboring first conductive layers.

6. The device of claim 1, wherein an upper end of the third conductive layer is included in a layer above an uppermost second conductive layer, and a lower end of the third conductive layer is included in a layer between an uppermost first conductive layer and a lowermost second conductive layer.

7. The device of claim 1, wherein the third conductive layer is silicon doped with impurities.

8. The device of claim 1, wherein the first conductive layer and the second conductive layer include the same material.

9. The device of claim 8, wherein the third conductive layer includes a material different from those of the first conductive layer and the second conductive layer.

10. The device of claim 1, wherein the pillar further includes a stacked film that includes a block insulating film between the first semiconductor layer and the first conductive layers, a charge storage layer between the block insulating film and the first semiconductor layer, and a tunnel insulating film between the charge storage layer and the first semiconductor layer.

11. The device of claim 10, wherein a film thickness of the gate insulating film is thinner than a film thickness of the stacked film.

12. The device of claim 10, wherein an outer diameter of the pillar in a cross-section parallel to a substrate and including one of the second conductive layers is smaller than an outer diameter in a cross-section parallel to the substrate and including one of the first conductive layers.

13. The device of claim 10, wherein
the stacked film is also provided between the second semiconductor layer and the second conductive layers, and
in the stacked film, a portion facing an uppermost first conductive layer and a portion facing a lowermost second conductive layer are continuously provided.

14. The device of claim 13, wherein a part of a side surface of the stacked film is aligned with a side surface of the third conductive layer.

15. The device of claim 13, wherein the stacked film provided between the second semiconductor layer and the second conductive layers is extending, as the gate insulating film, between the second semiconductor layer and the third conductive layer.

16. The device of claim 2, wherein the second conductive layers contact a side surface of the third conductive layer.

17. The device of claim 1, wherein end portions of the second conductive layers are provided in a stepped fashion, each of the second conductive layers having a terrace portion that does not overlap with an above second conductive layer, and a contact is coupled to each of the terrace portions of the second conductive layers.

18. The device of claim 1, further comprising a contact penetrating the second conductive layers, the contact being electrically coupled to the second conductive layers, and a bottom part of the contact being provided apart from an uppermost first conductive layer.

19. A method of manufacturing a semiconductor memory device, comprising:
forming a first stacked portion in which a plurality of first sacrificial members are stacked apart from each other;
forming a plurality of first holes that each penetrate the first stacked portion;
forming a block insulating film, a charge storage layer, a tunnel insulating film, and a first semiconductor layer in sequence in the first holes;
after forming the first semiconductor layer in the first holes, forming a second stacked portion in which a plurality of second sacrificial members are stacked apart from each other above the first stacked portion;
forming a first slit that divides the second stacked portion;
forming a third sacrificial member in the first slit;
after forming the third sacrificial member, forming a plurality of second holes that each penetrate the second stacked portion and overlap each of the first holes;
forming a conductive layer, a gate insulating film, and a second semiconductor layer in sequence in the second holes;
after forming the second semiconductor layer in the second holes, forming a second slit that divides the first stacked portion and the second stacked portion; and
after forming the second slit, removing the first sacrificial member, the second sacrificial member, and the third sacrificial member, and forming a conductor in a space from which the first sacrificial member and the second sacrificial member are removed.

20. A method of manufacturing a semiconductor memory device, comprising:
forming a first stacked portion in which a plurality of first sacrificial members are stacked apart from each other, and forming a second stacked portion in which a plurality of second sacrificial members are stacked apart from each other above the first stacked portion;
forming a first slit that divides the second stacked portion;
forming a third sacrificial member in the first slit;
after forming the third sacrificial member, forming a plurality of holes that each penetrate the first stacked portion and the second stacked portion;
selectively forming a conductive layer at a portion facing the second stacked portion in the holes;
after selectively forming the conductive layer, forming a block insulating film, a charge storage layer, a tunnel insulating film, and a semiconductor layer in sequence in the holes;
after forming the semiconductor layer in the holes, forming a second slit that divides the first stacked portion and the second stacked portion; and
after forming the second slit, removing the first sacrificial member, the second sacrificial member, and the third sacrificial member, and forming a conductor in a space from which the first sacrificial member and the second sacrificial member are removed.
